(19) United States
(12) Patent Application Publication
(10) Pub. No.: US 2025/0113604 A1
(43) Pub. Date: Apr. 3, 2025

(54) SEMICONDUCTOR STRUCTURE WITH DOPED REGION AND METHOD FOR MANUFACTURING THE SAME

(71) Applicant: Taiwan Semiconductor Manufacturing Company, Ltd., Hsinchu (TW)

(72) Inventors: Kenichi SANO, Hsinchu (TW); Chia-Yun CHENG, Hsinchu City (TW); Yu-Wei LU, Taipei City (TW); I-Ming CHANG, ShinChu (TW); Pinyen LIN, Rochester, NY (US)

(73) Assignee: Taiwan Semiconductor Manufacturing Company, Ltd., Hsinchu (TW)

(21) Appl. No.: 18/477,940

(22) Filed: Sep. 29, 2023

(51) Int. Cl. H01L 27/092; H01L 21/28; H01L 21/822; H01L 21/8238; H01L 29/06; H01L 29/423; H01L 29/66; H01L 29/775

(52) U.S. Cl. CPC H10D 84/856; H01L 21/28185; H10D 30/014; H10D 30/43; H10D 30/6735; H10D 62/121; H10D 64/017; H10D 84/0167; H10D 84/0181; H10D 84/038; H10D 88/01

(57) ABSTRACT

Semiconductor structures and methods for manufacturing the same are provided. The method includes forming first channel structures, second channel structures, and third channel structures. The method also includes forming gate dielectric layers surrounding the first channel structures, the second channel structures, and the third channel structures and forming dipole layers over the gate dielectric layers. The method also includes forming a dummy material in a first space between the first and the second channel structures and in a second space between the second and the third channel structures and removing first portions of the dummy material. The method also includes implanting first dopants in the dummy material in the first space and removing second portions of the dummy material in the first space and the second space. The method also includes removing the dipole layers in the top device region and completely removing the dummy material.

### BACKGROUND

The electronics industry is experiencing ever-increasing demand for smaller and faster electronic devices that are able to perform a greater number of increasingly complex and sophisticated functions. Accordingly, there is a continuing trend in the semiconductor industry to manufacture low-cost, high-performance, and low-power integrated circuits (ICs). So far, these goals have been achieved in large part by scaling down semiconductor IC dimensions (e.g., minimum feature size) and thereby improving production efficiency and lowering associated costs. However, such miniaturization has introduced greater complexity into the semiconductor manufacturing process. Thus, the realization of continued advances in semiconductor ICs and devices calls for similar advances in semiconductor manufacturing processes and technology.

Recently, complementary FET (CFET) have been introduced. In a CFET structure, nMOS and pMOS devices are stacked on top of each other, so that the effective channel width of the resulting device may be further maximized. However, integration of fabrication of the CFET devices can be challenging.

### BRIEF DESCRIPTION OF THE DRAWINGS

Aspects of the present disclosure are best understood from the following detailed description when read with the accompanying Figures. It should be noted that, in accordance with the standard practice in the industry, various features are not drawn to scale. In fact, the dimensions of the various features may be arbitrarily increased or reduced for clarity of discussion.

FIGS. 1A to 1P, 1A-1 to 1D-1, and 1A-2 to 1D-2 illustrate cross-sectional views of intermediate stages of manufacturing a semiconductor structure in accordance with some embodiments.

FIG. 1A-3 illustrates a diagrammatic perspective view of the intermediate stage of manufacturing the semiconductor structure shown in FIGS. 1A-1, 1A-2, and 1A-3 in accordance with some embodiments.

FIG. 1A-4 illustrates a diagrammatic top view of the intermediate stage of manufacturing the semiconductor structure shown in FIGS. 1A, 1A-1, 1A-2, and 1A-3 in accordance with some embodiments.

FIG. 1B-3 illustrates a diagrammatic top view of the intermediate stage of the semiconductor structure shown in FIGS. 1B to 1B-2 in accordance with some embodiments.

FIG. 11-1 illustrates a diagrammatic top view of an intermediate stage of the semiconductor structure shown in FIG. 1I in accordance with some embodiments.

FIG. 11-2 illustrates a cross-sectional view of an intermediate stage of the semiconductor structure shown alone line X_{Sp2} to X_{Sp2}′ in FIG. 11-1 in accordance with some embodiments.

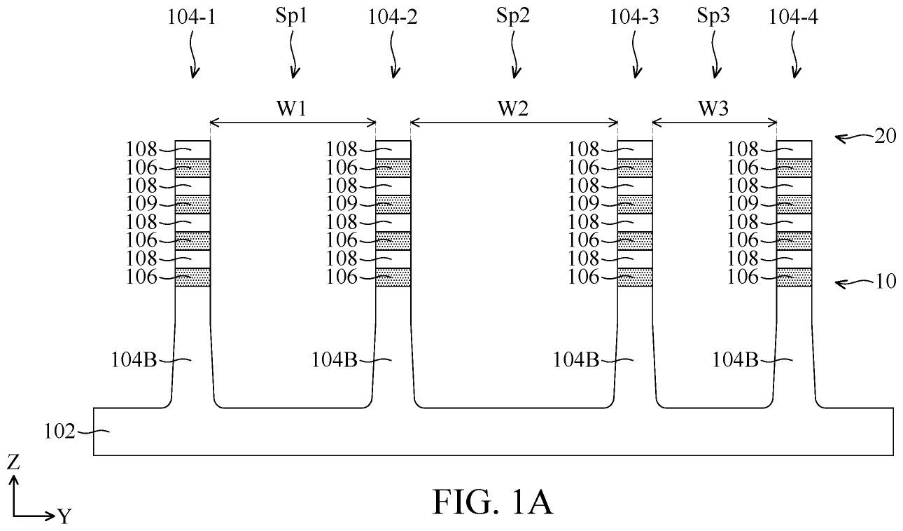

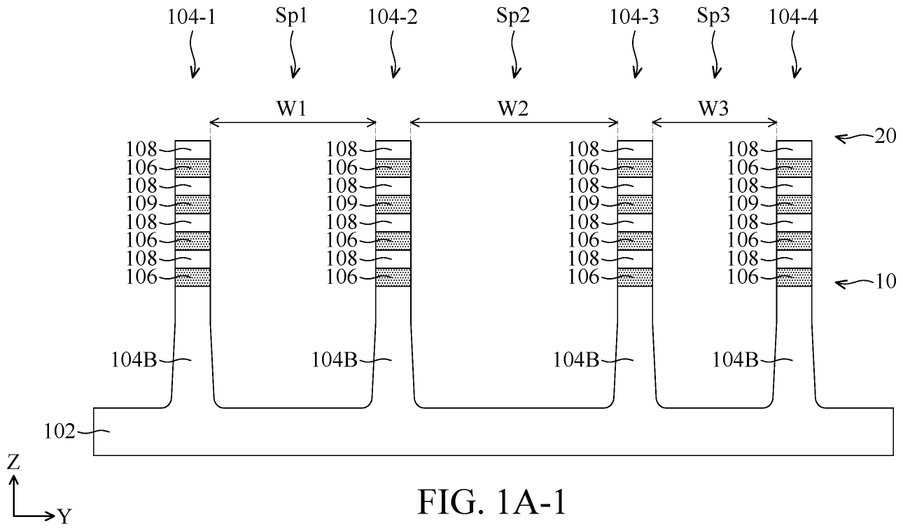

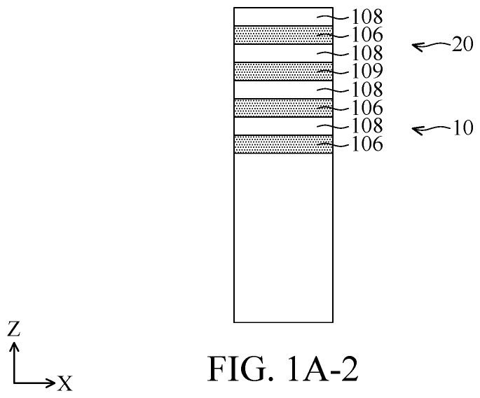

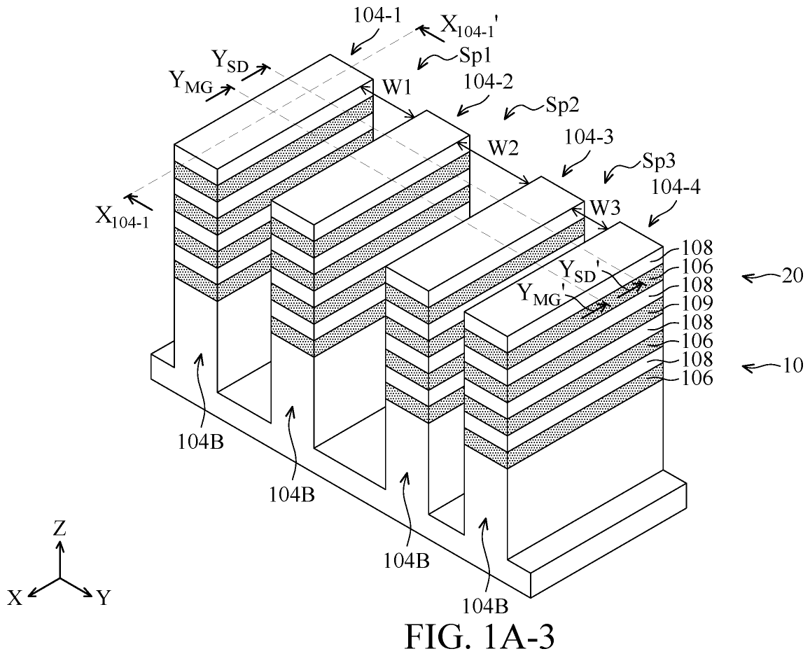

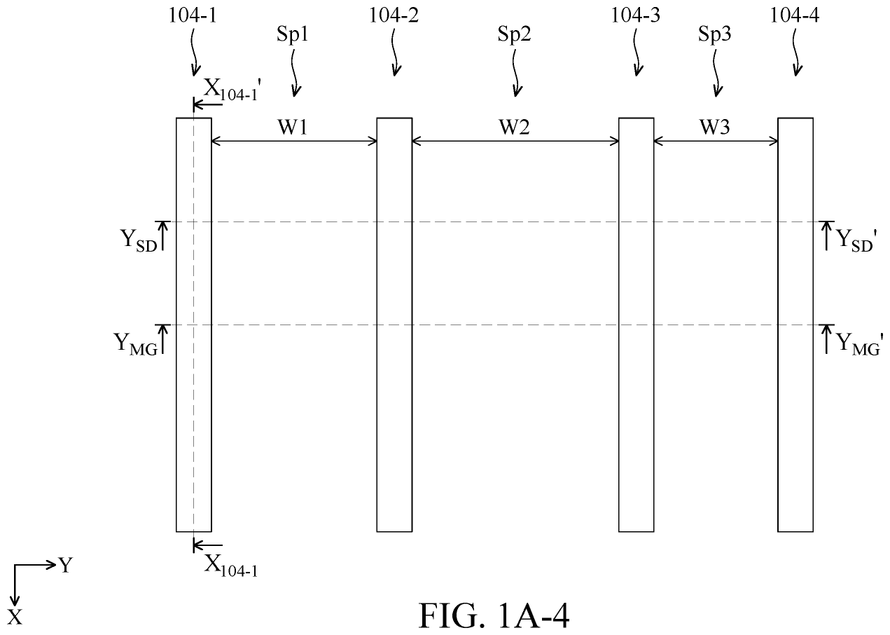

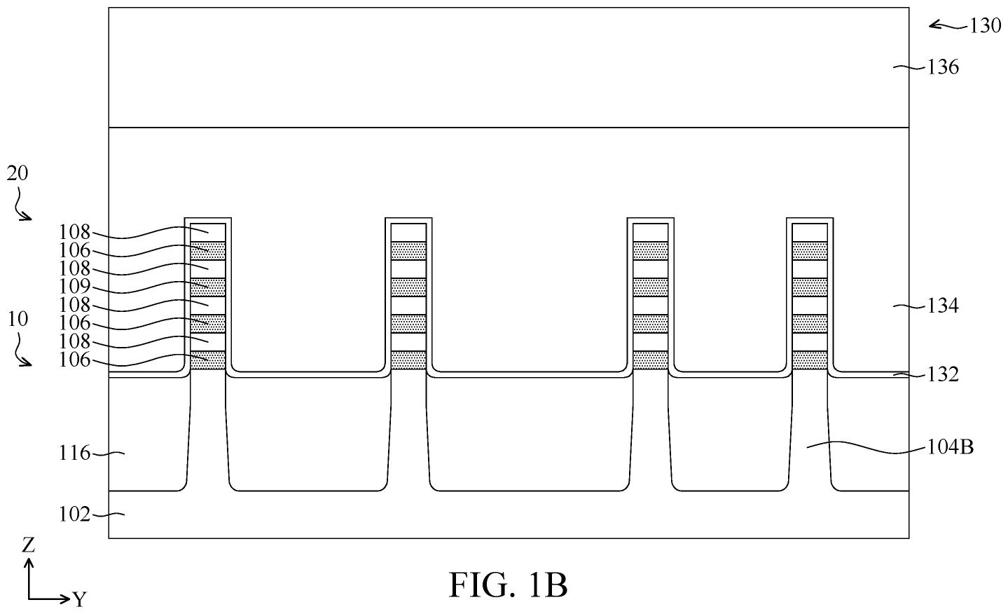

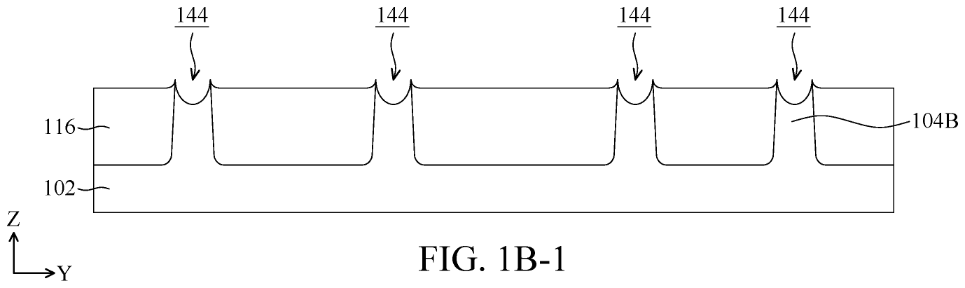

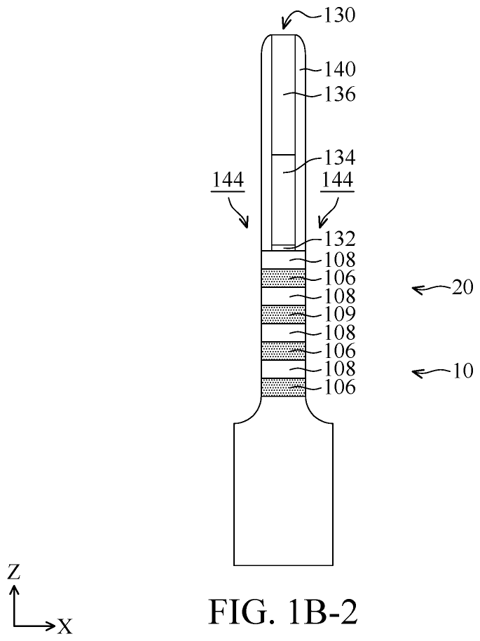

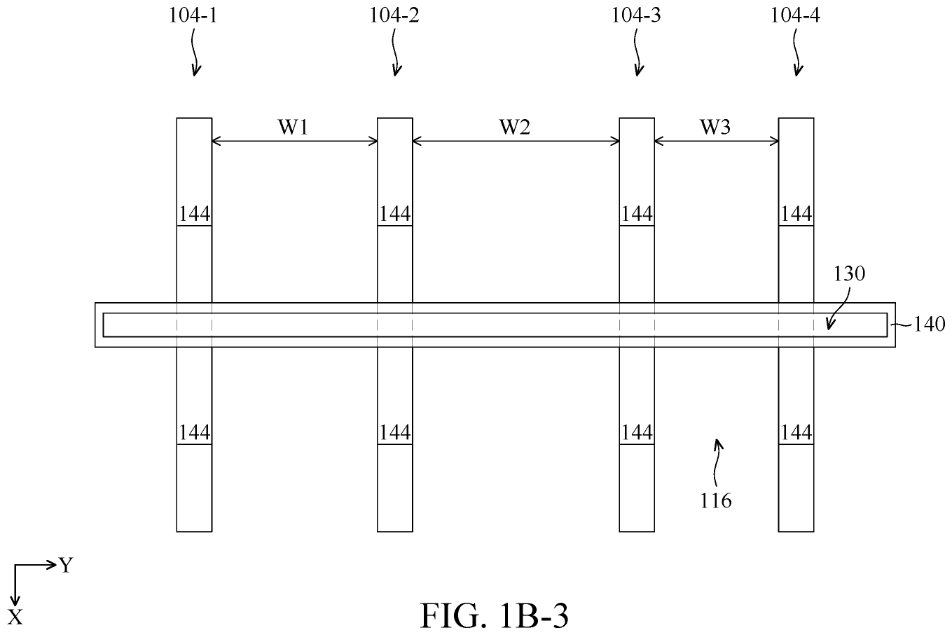

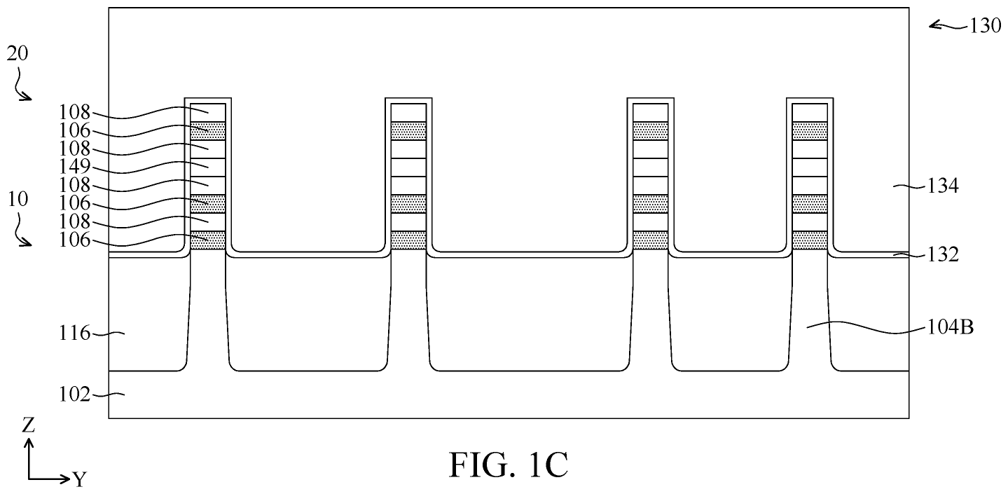

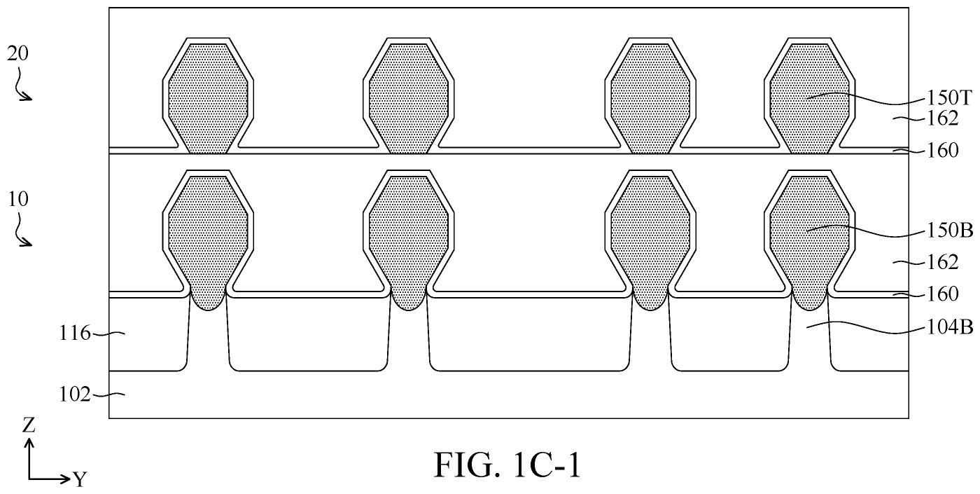

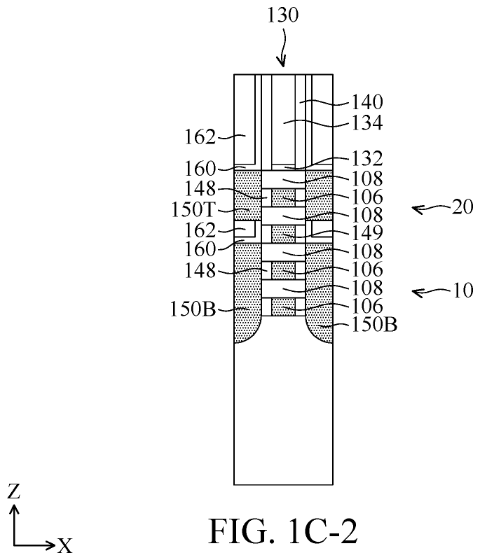

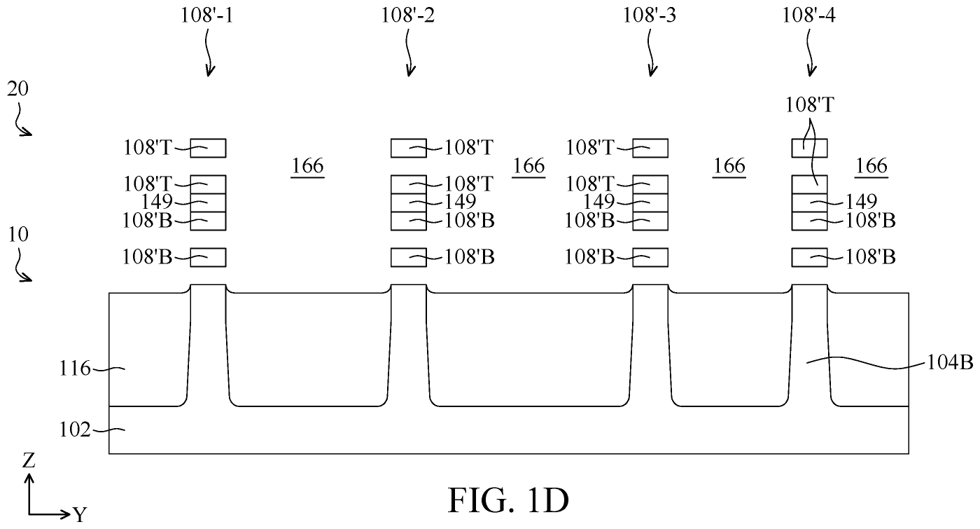

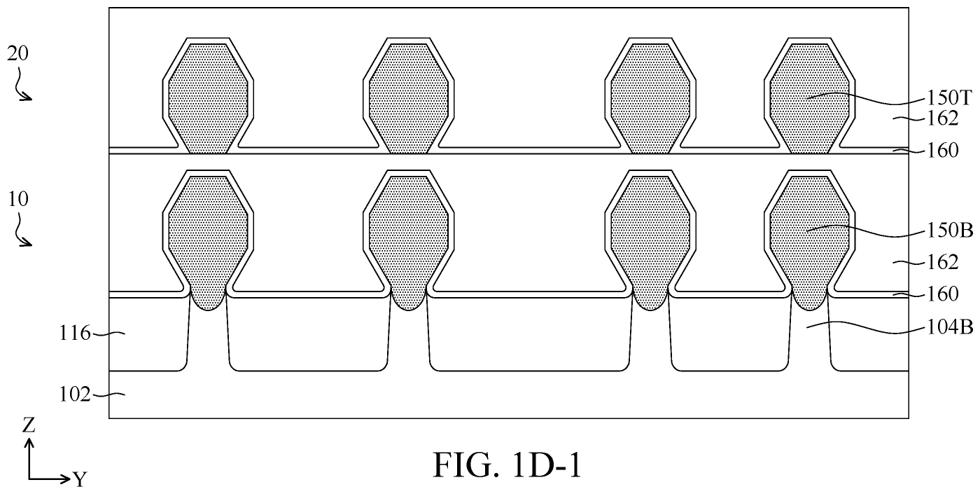

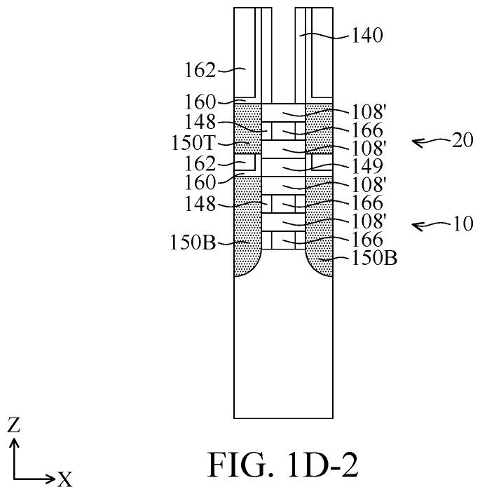

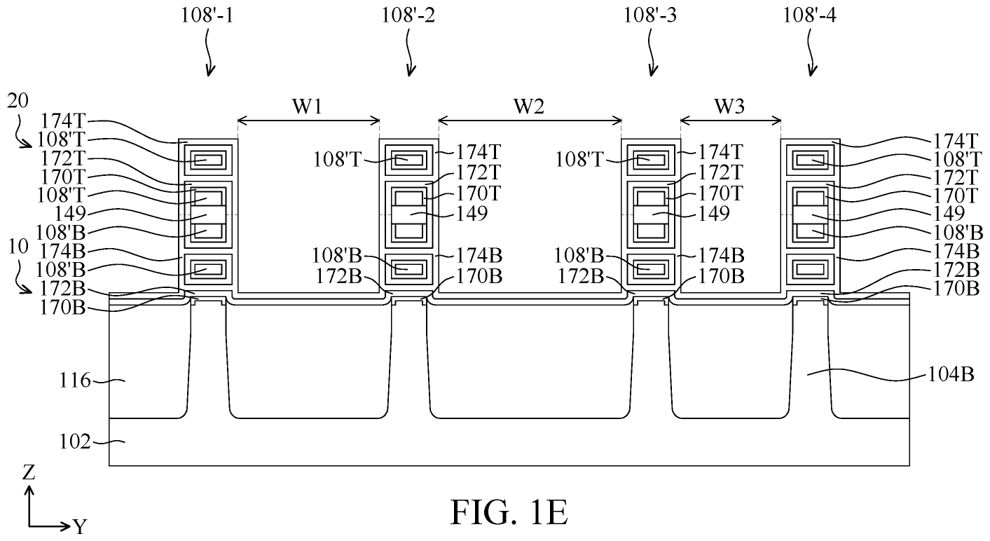

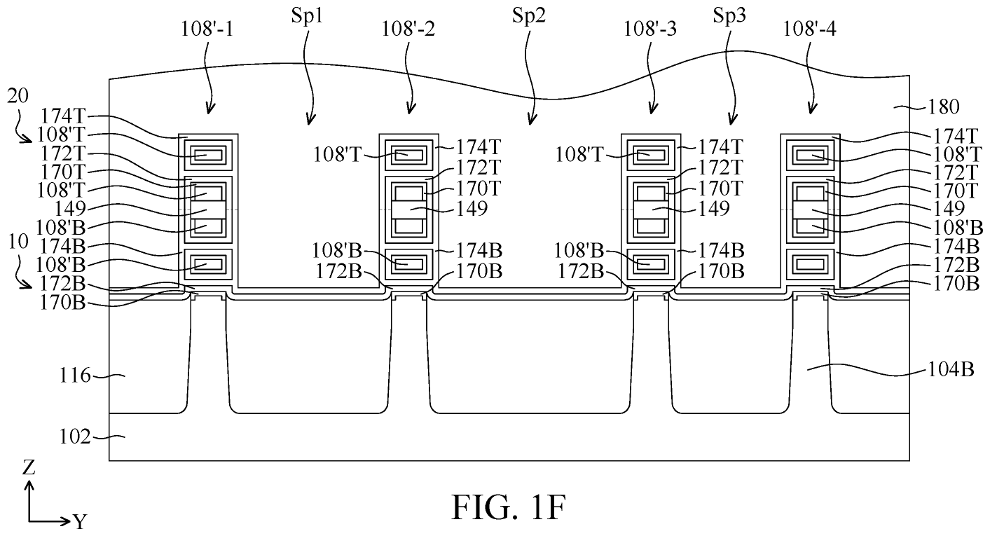

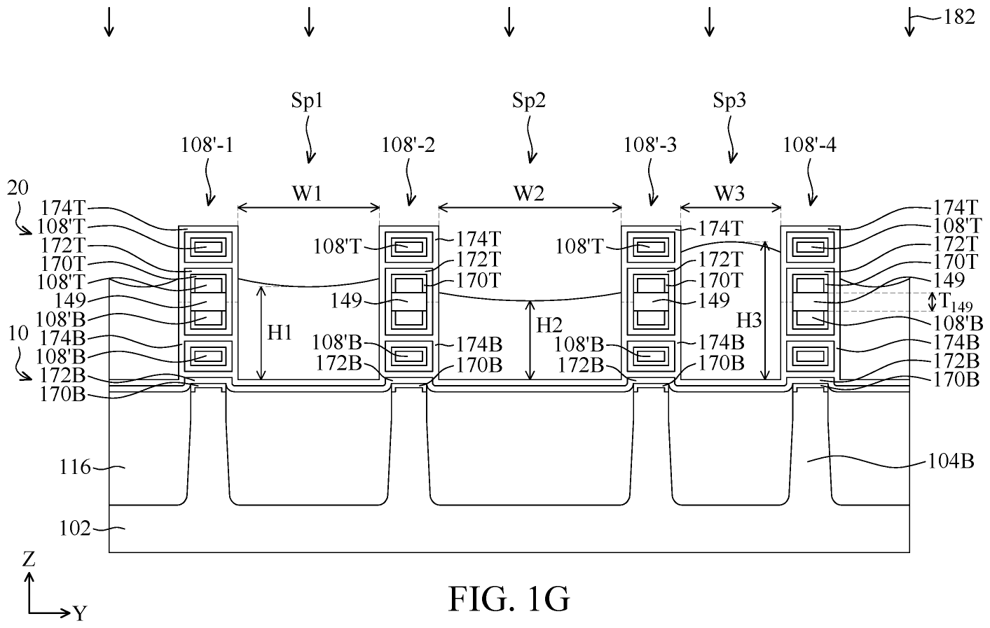

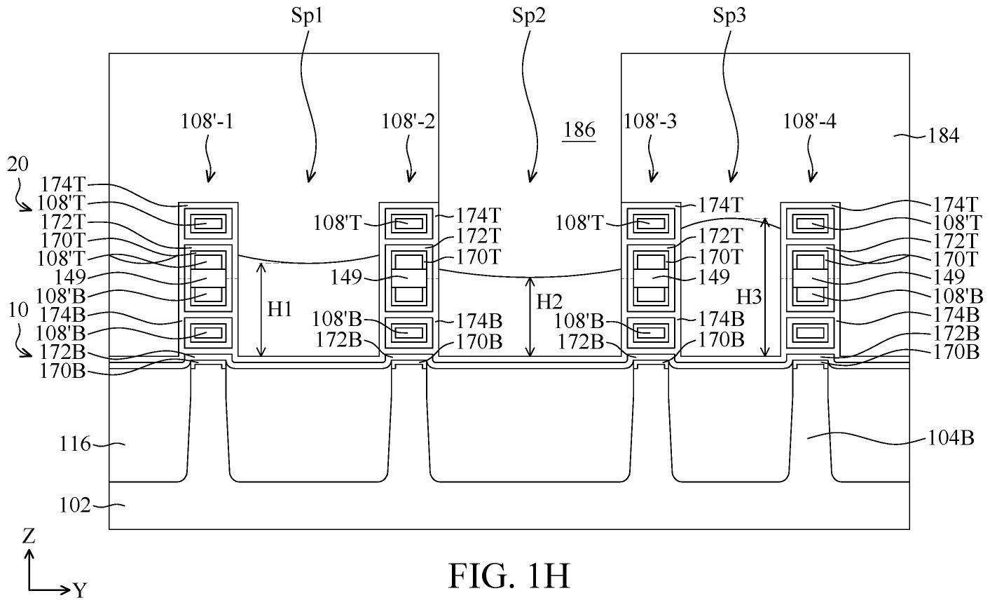

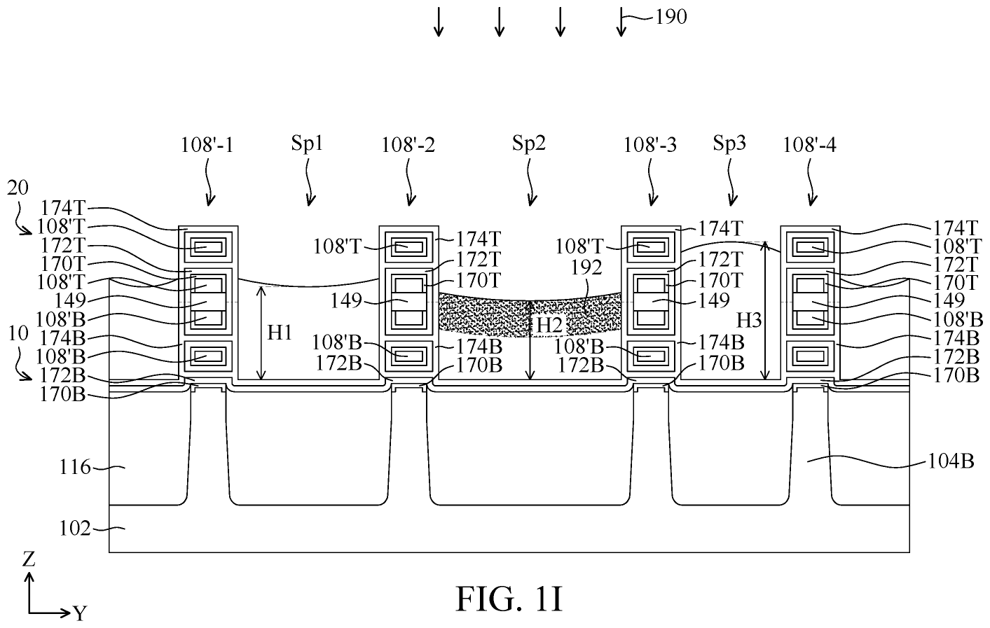

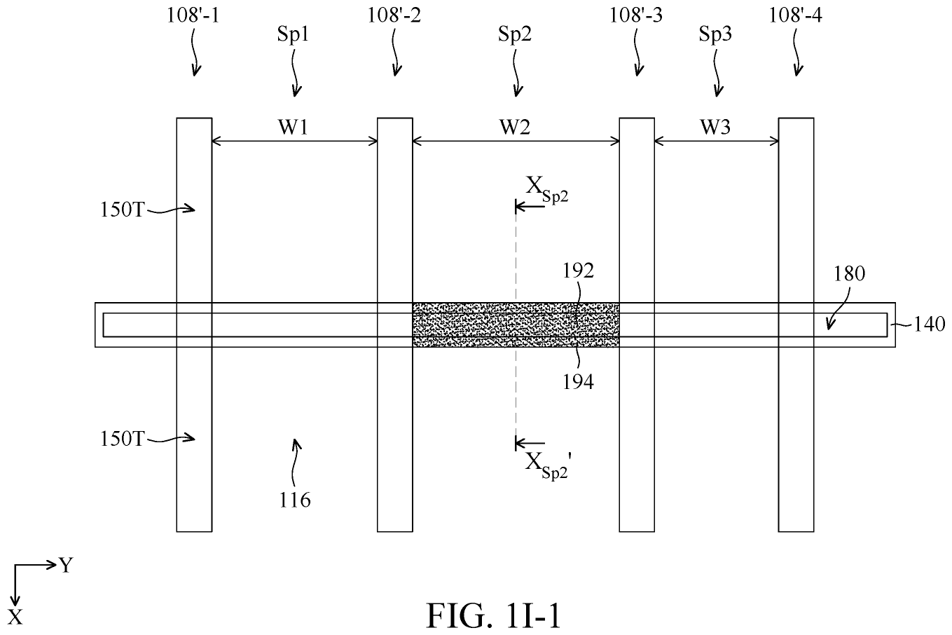

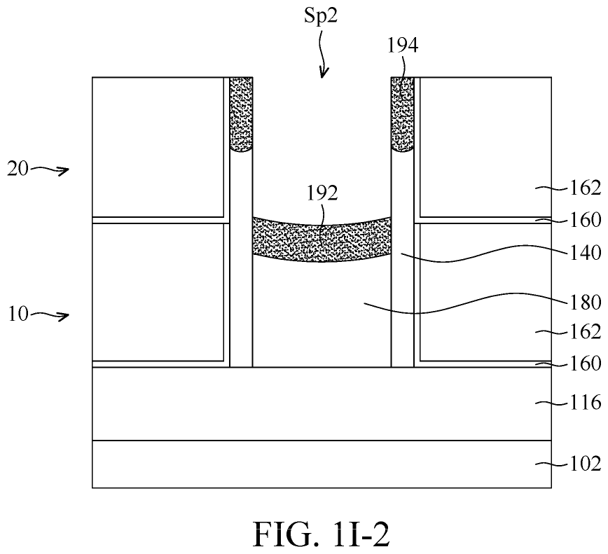

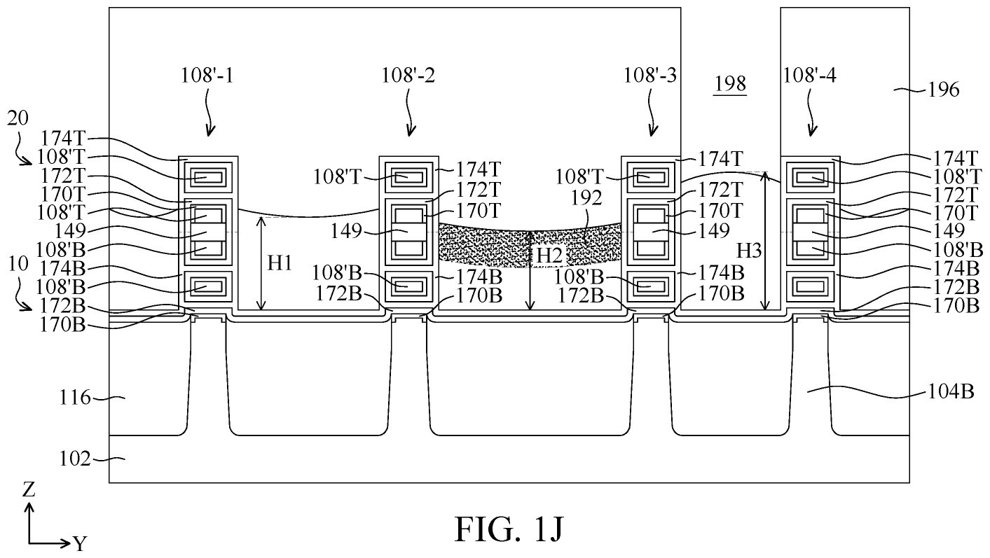

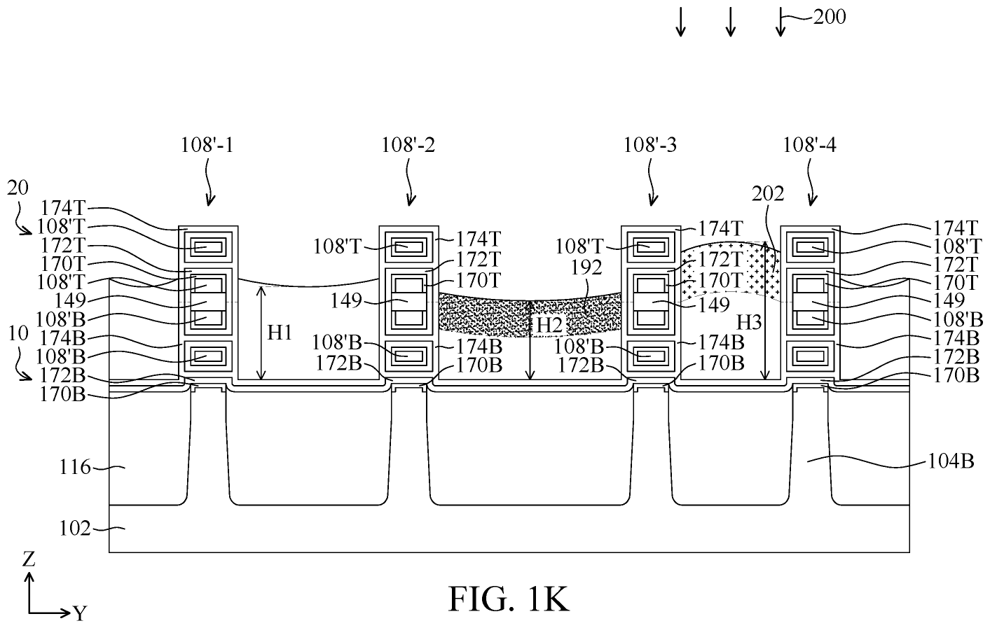

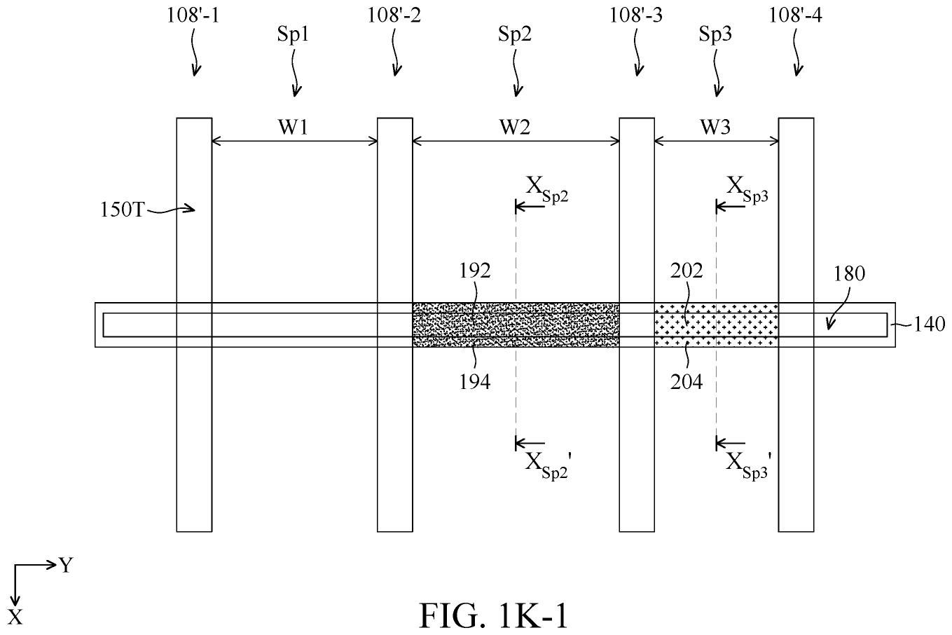

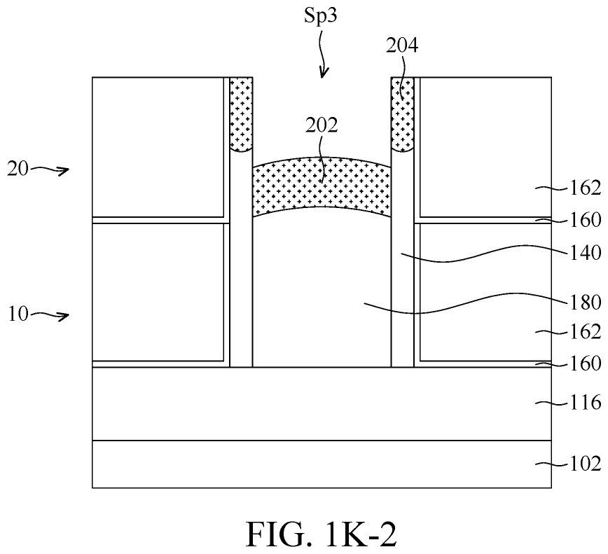

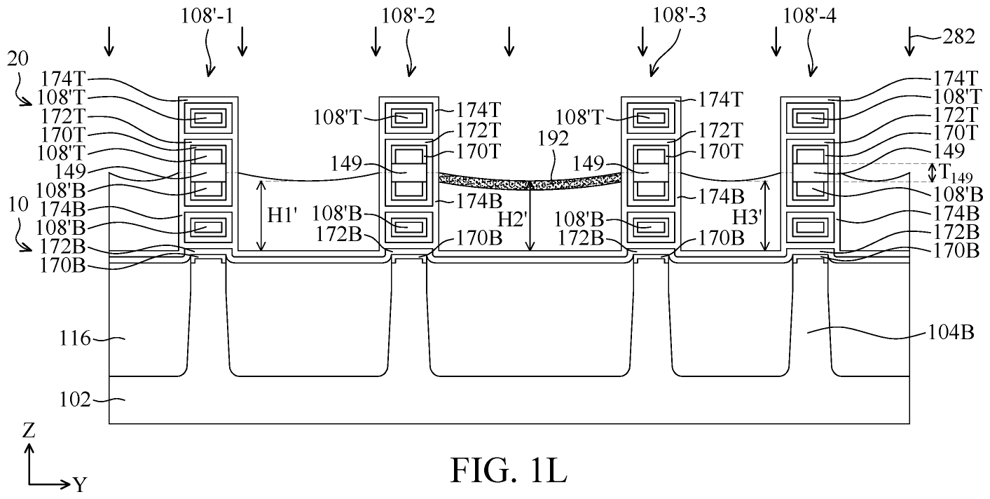

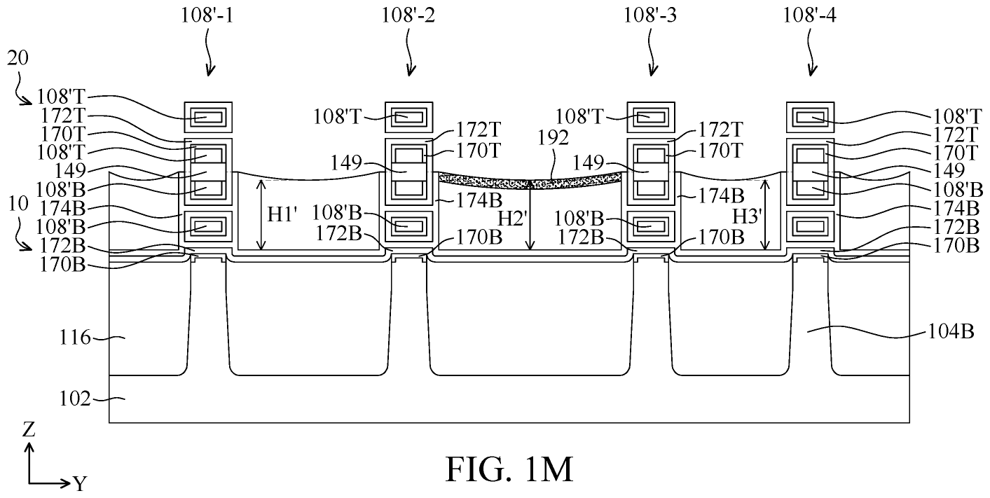

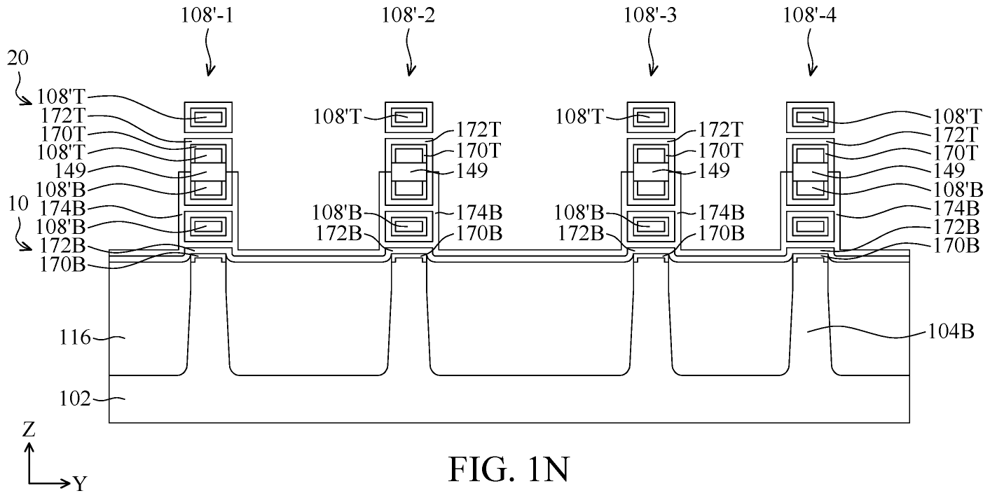

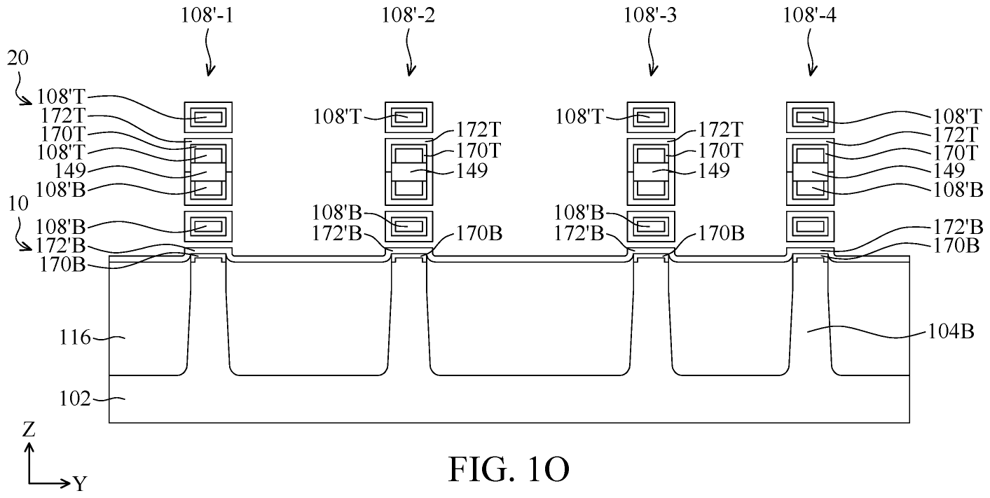

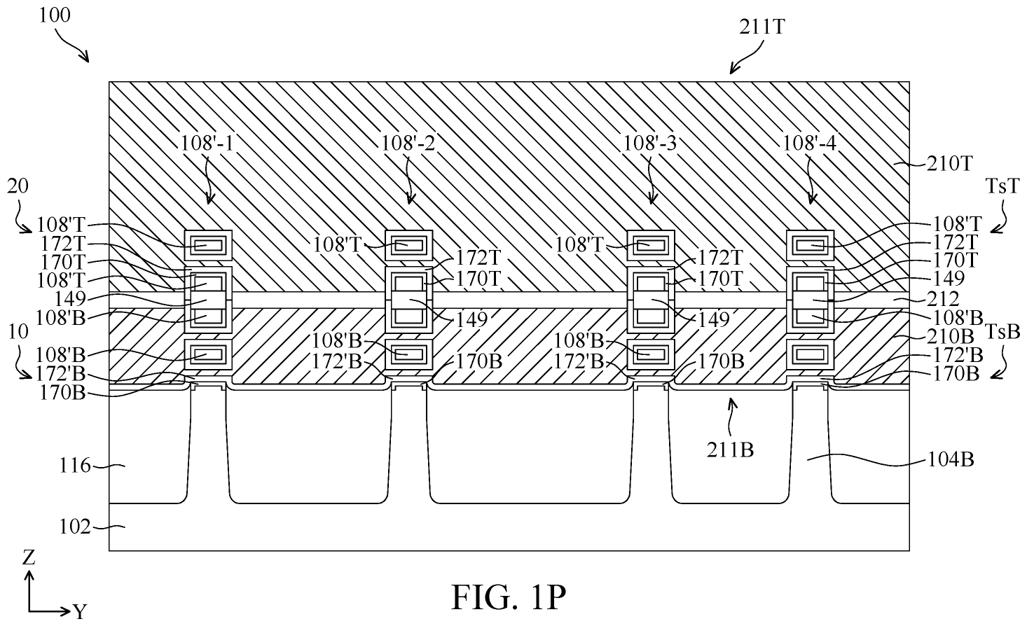

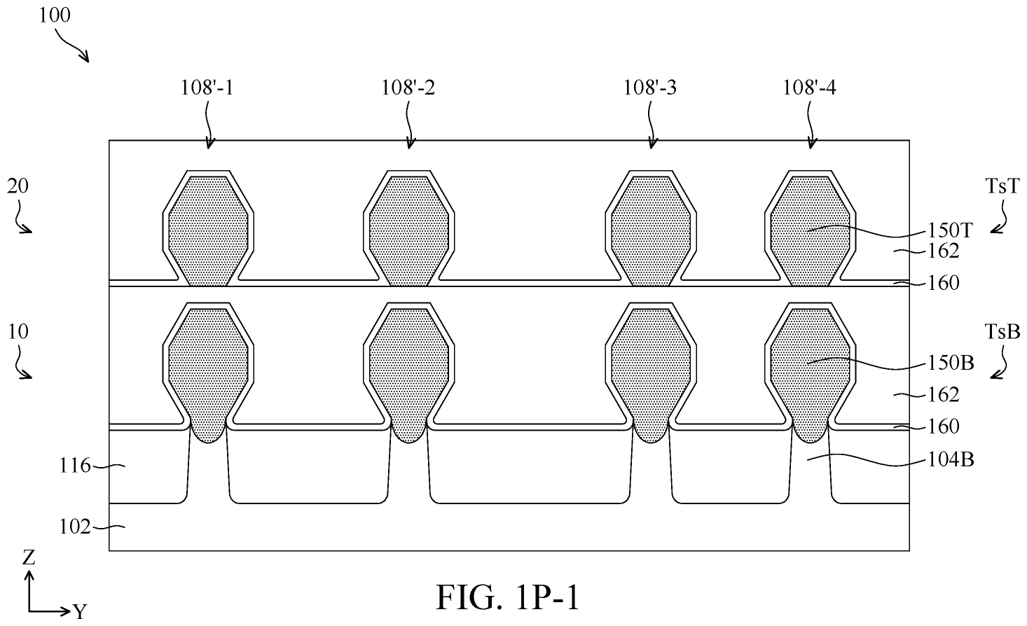

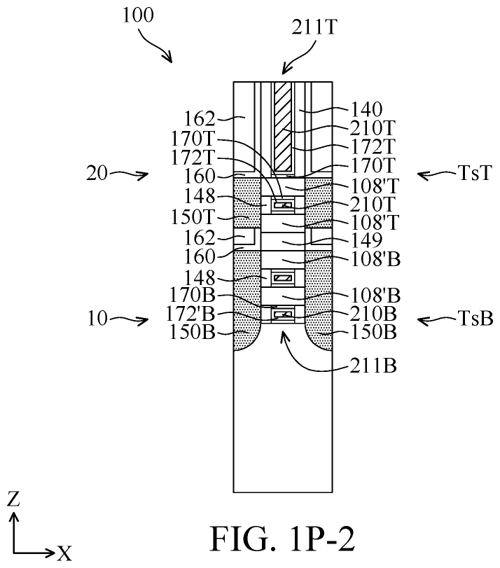

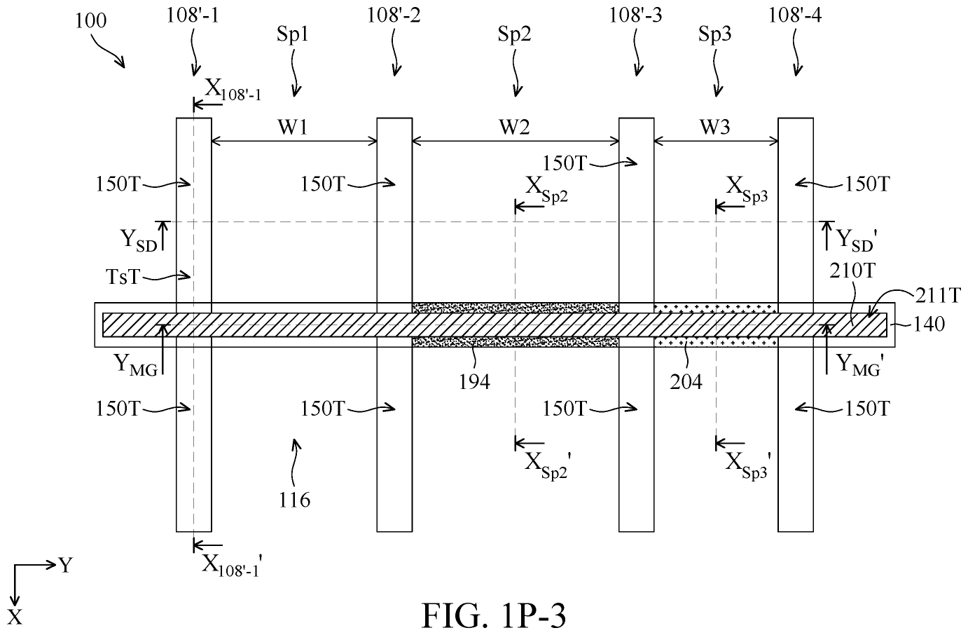

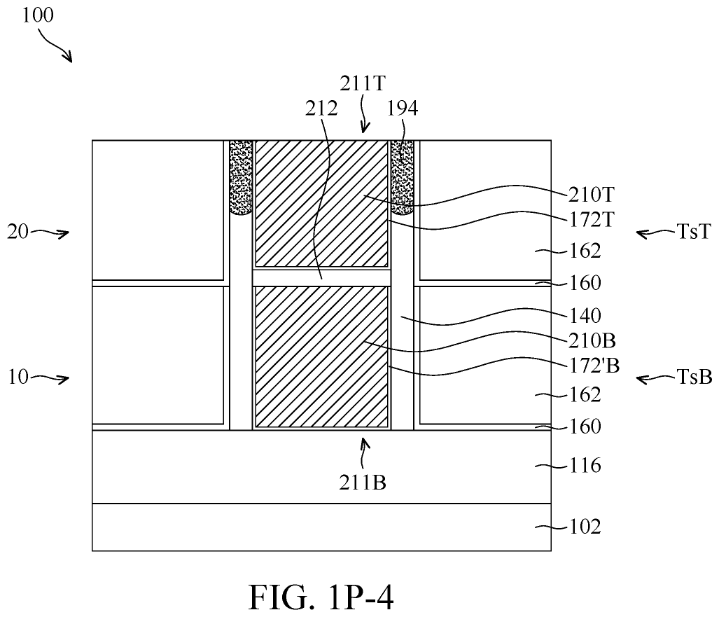

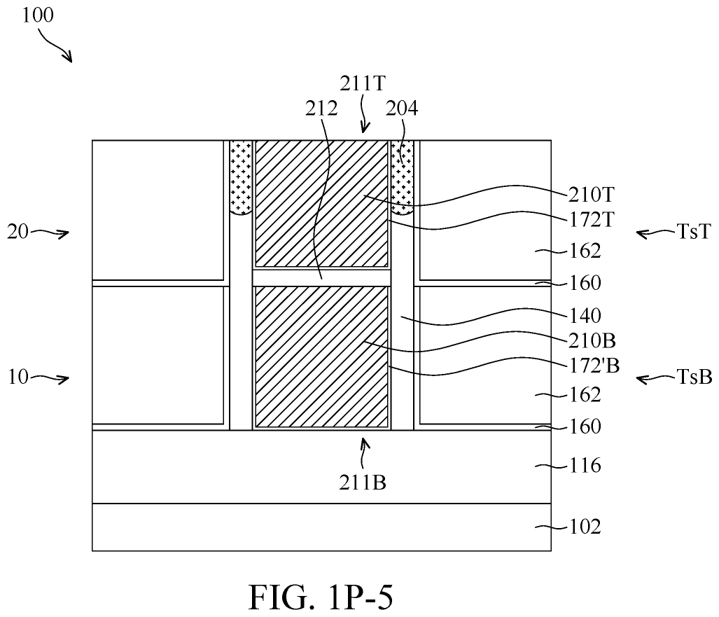

FIG. 1K-1 illustrates a diagrammatic top view of an intermediate stage of the semiconductor structure shown in FIG. 1K in accordance with some embodiments.

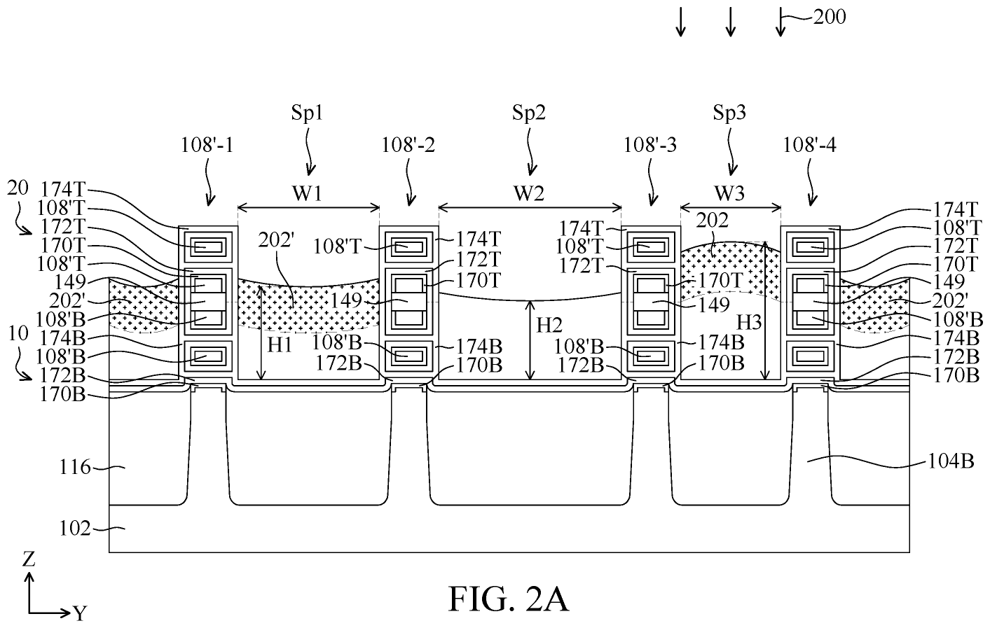

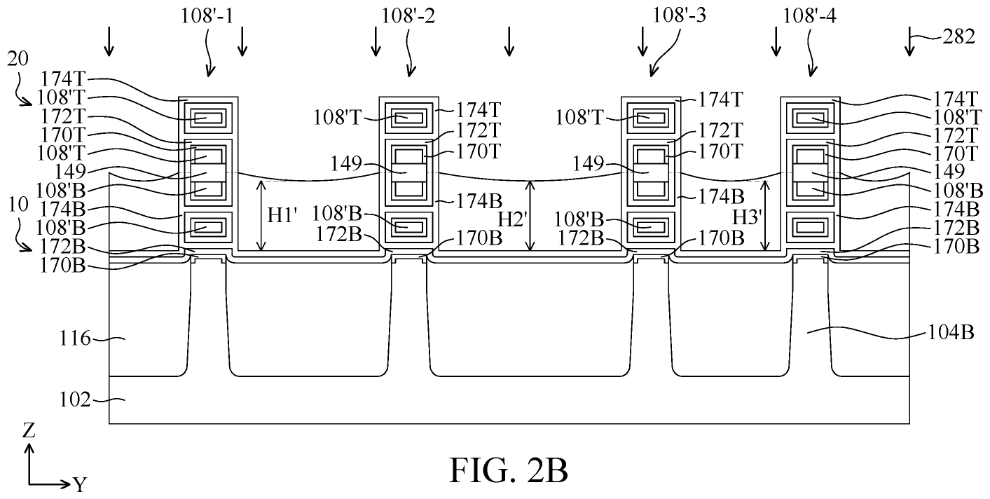

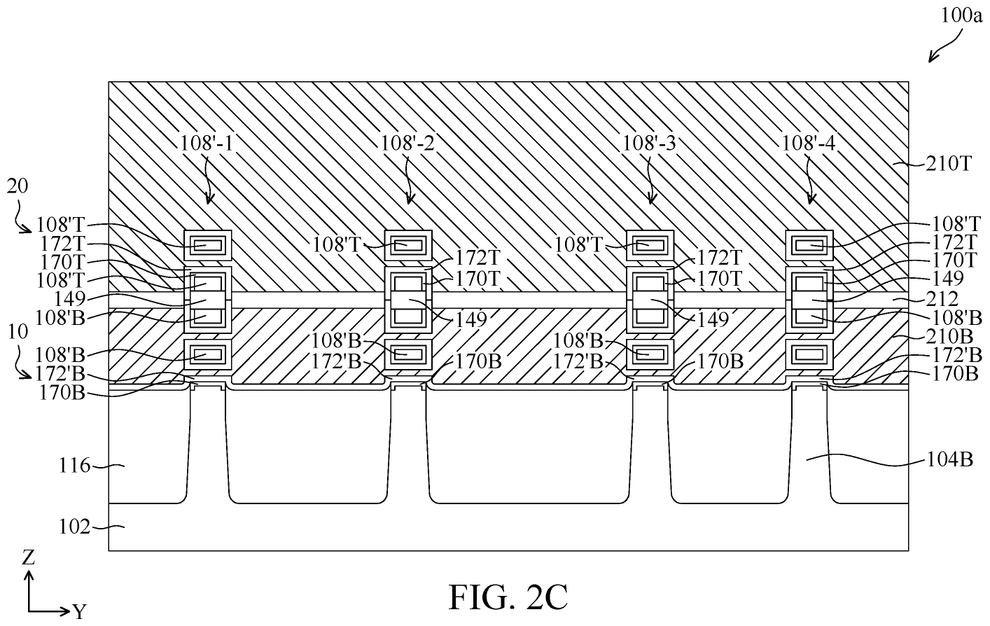

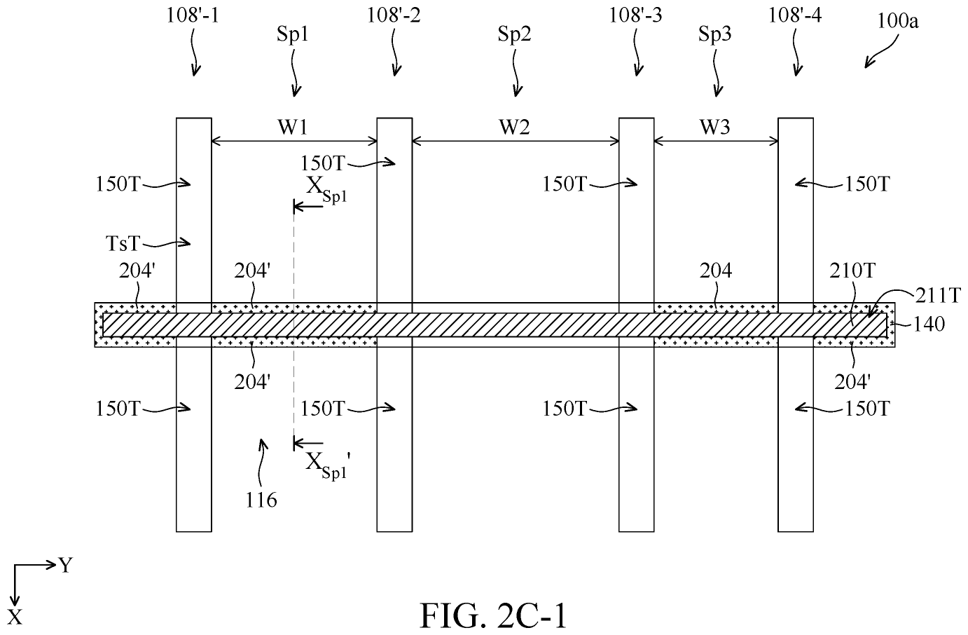

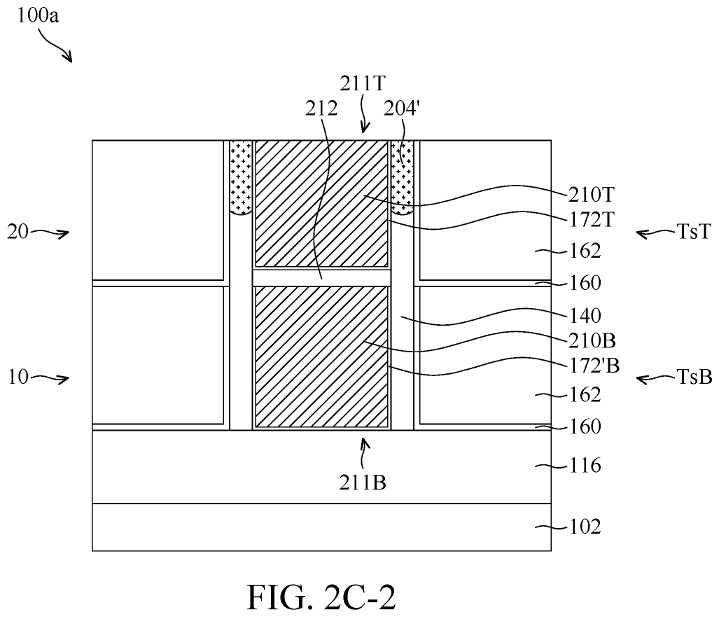

FIG. 1K-2 illustrates a cross-sectional view of an intermediate stage of the semiconductor structure shown alone line X_{Sp3} to X_{Sp3}′ in FIG. 1K-1 in accordance with some embodiments.

FIG. 1P-3 illustrates the top view of the semiconductor structure in accordance with some embodiments.

FIGS. 1P, 1P-1, and 1P-2 illustrate cross-sectional views of the semiconductor structure shown along line Y_{MG}-Y_{MG}′ (i.e. in the Y direction), Y_{SD}-Y_{SD}′ (i.e. in the Y direction), and X_{108′-1}-X_{108′-1}′ (i.e. in the X direction) in FIG. 1P-3, respectively, in accordance with some embodiments.

FIG. 1P-4 illustrates a cross-sectional view of the semiconductor structure shown along line X_{Sp2} to X_{Sp2}′ in FIG. 1P-3 in accordance with some embodiments.

FIG. 1P-5 illustrates a cross-sectional view of the semiconductor structure shown alone line X_{Sp3} to X_{Sp3}′ in FIG. 1P-3 in accordance with some embodiments.

FIGS. 2A to 2C illustrate cross-sectional views of intermediate stages of manufacturing a semiconductor structure in accordance with some embodiments.

FIG. 2C-1 illustrates the top view of the semiconductor structure in accordance with some embodiments.

FIG. 2C-2 illustrates a cross-sectional view of the semiconductor structure shown along line X_{Sp1} to X_{Sp1}′ in FIG. 2C-1 in accordance with some embodiments.

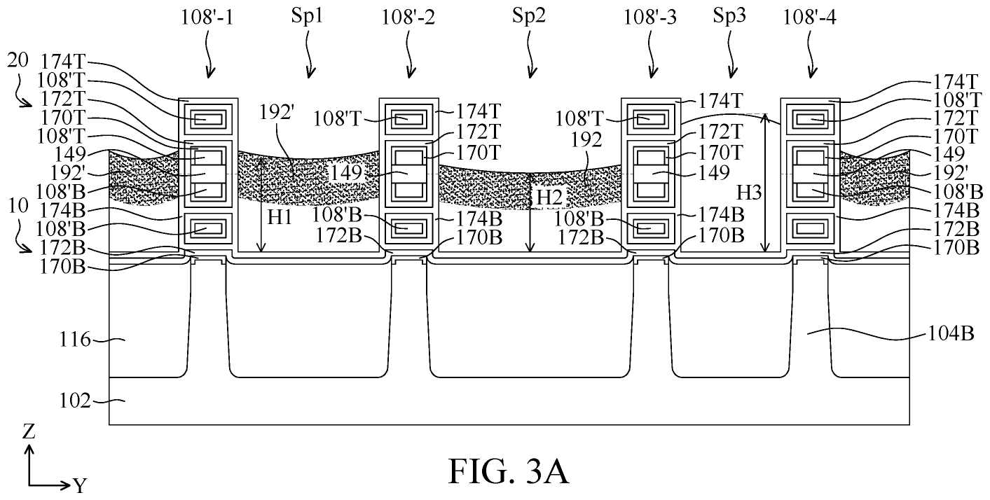

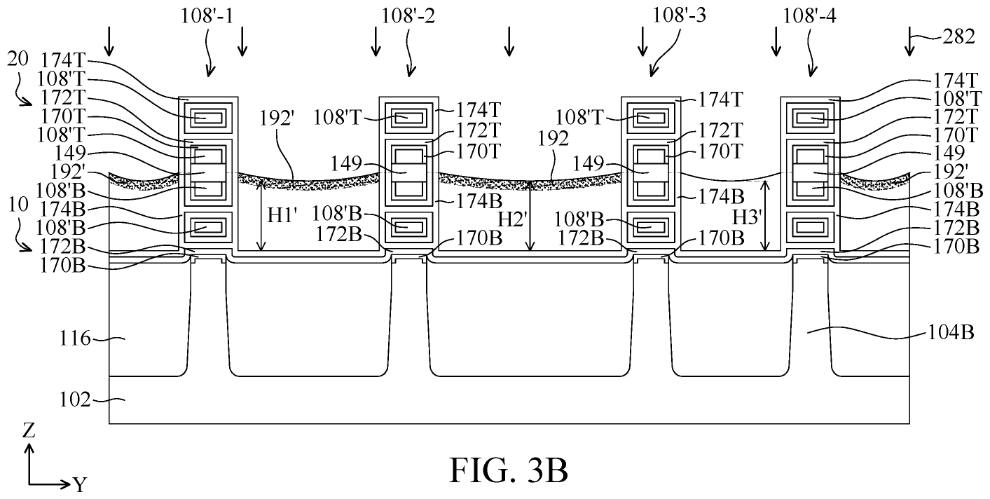

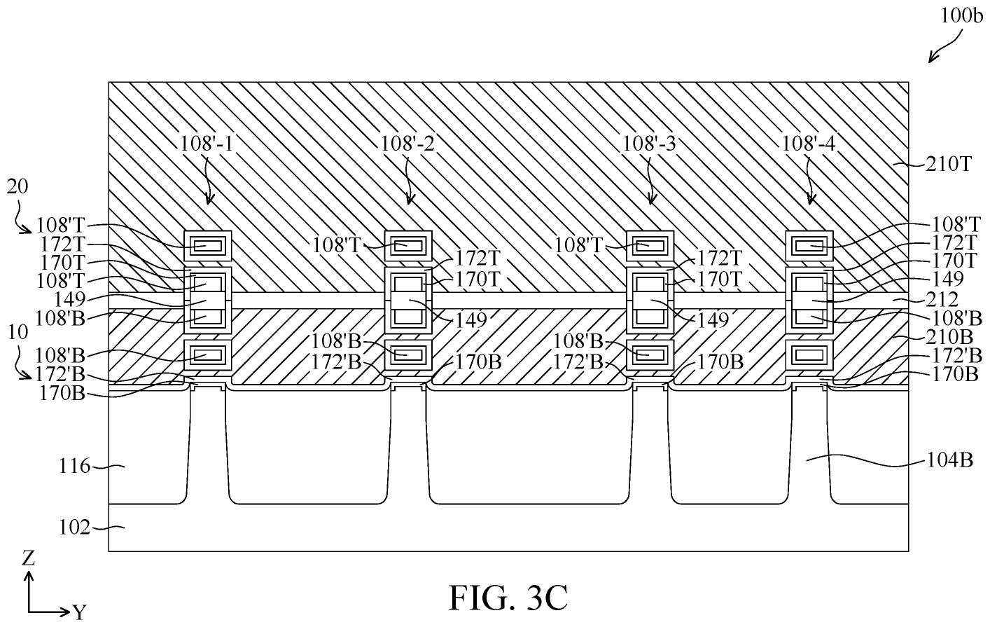

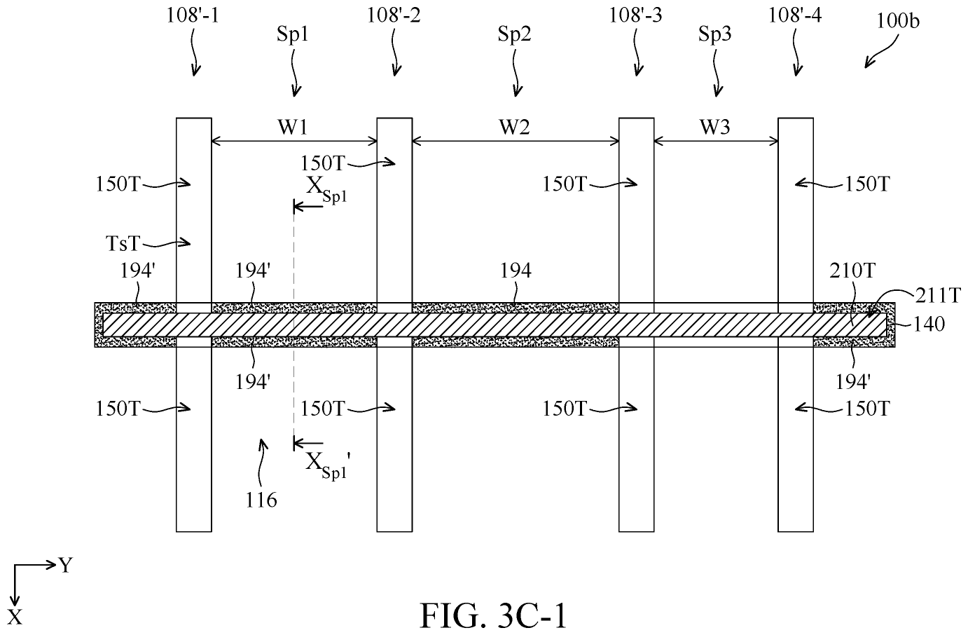

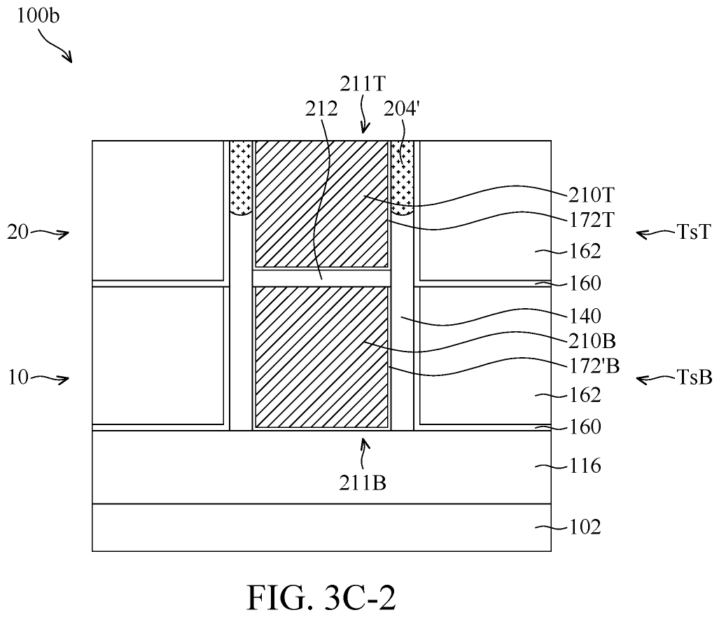

FIGS. 3A to 3C illustrate cross-sectional views of intermediate stages of manufacturing a semiconductor structure in accordance with some embodiments.

FIG. 3C-1 illustrates the top view of the semiconductor structure in accordance with some embodiments.

FIG. 3C-2 illustrates a cross-sectional view of the semiconductor structure shown along line X_{Sp1} to X_{Sp1}′ in FIG. 3C-1 in accordance with some embodiments.

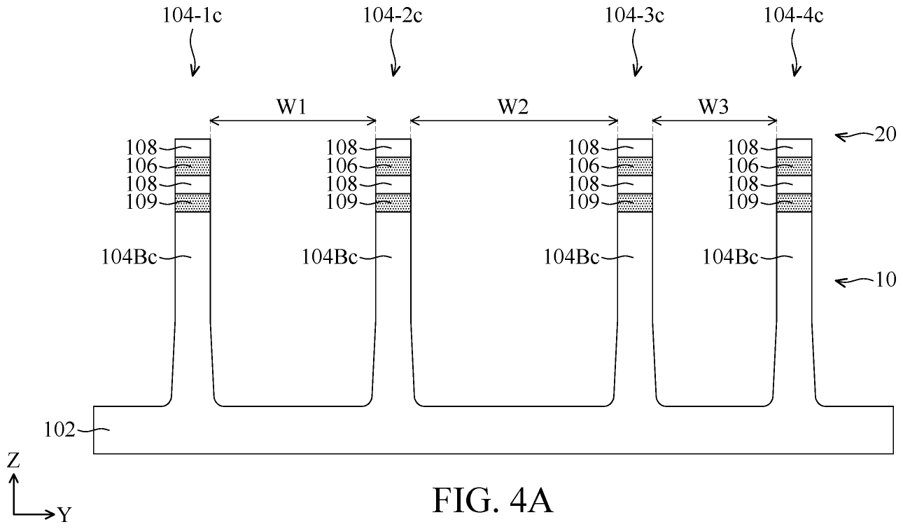

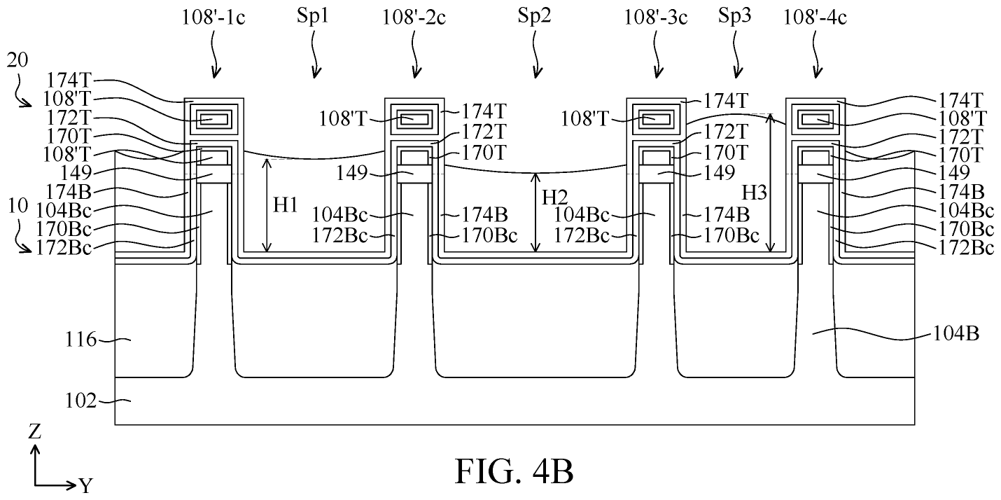

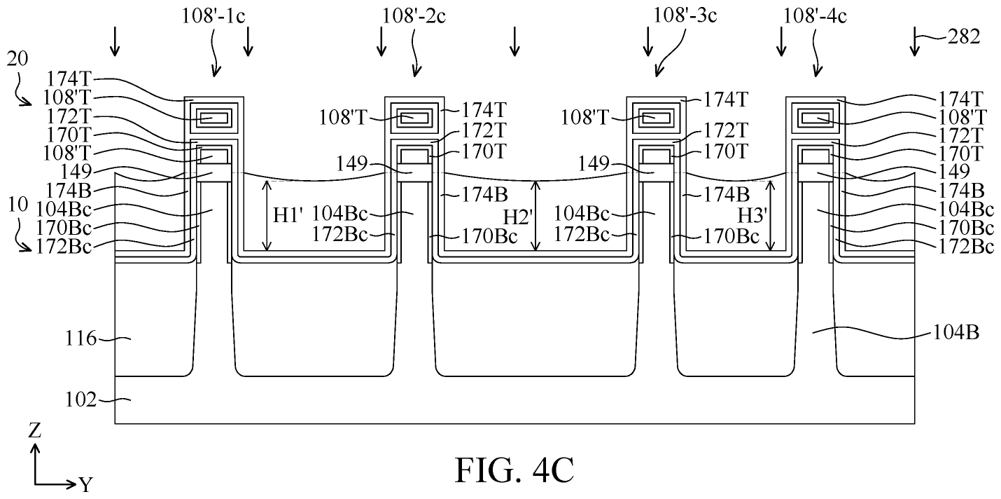

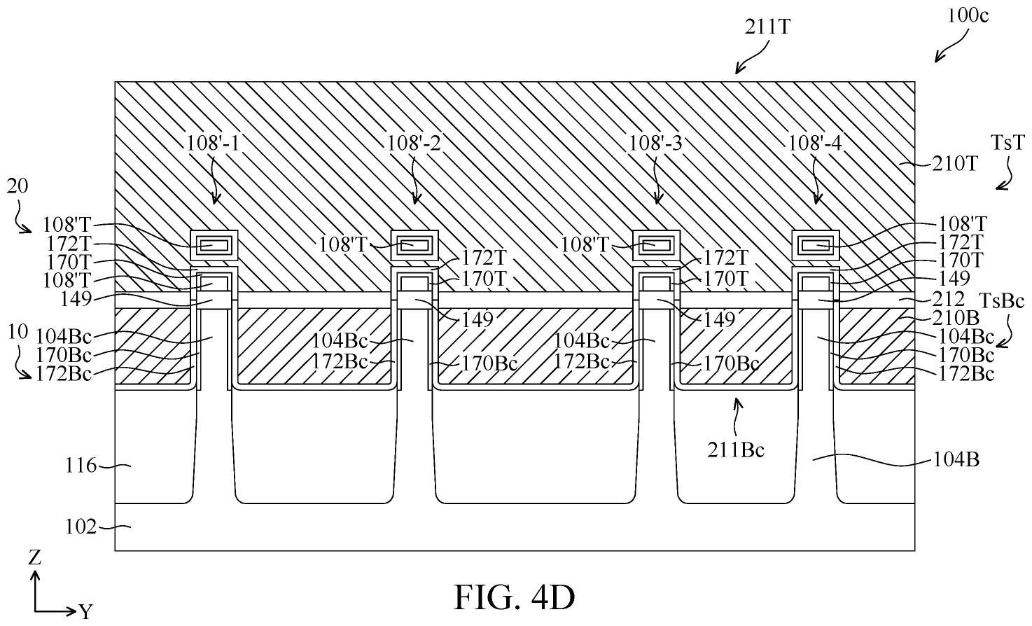

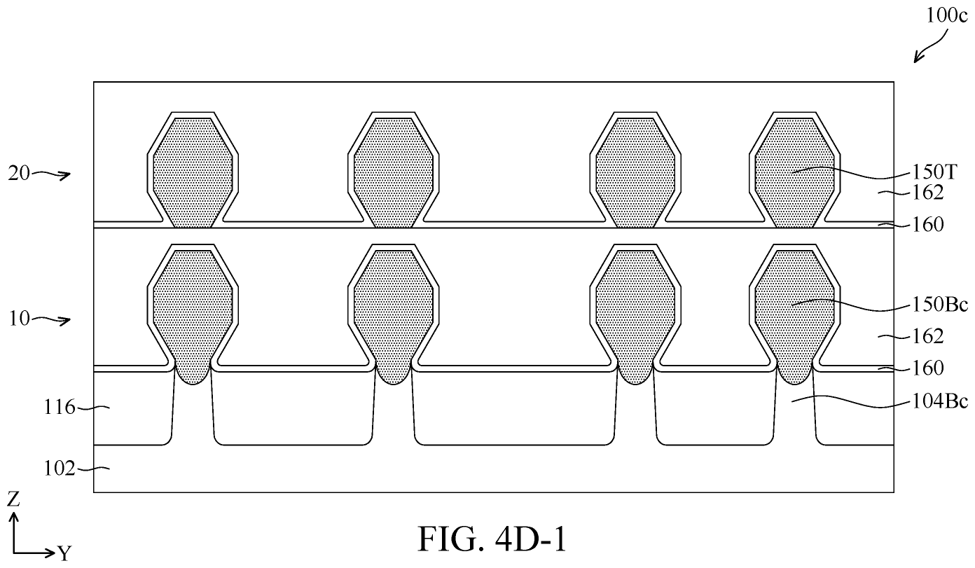

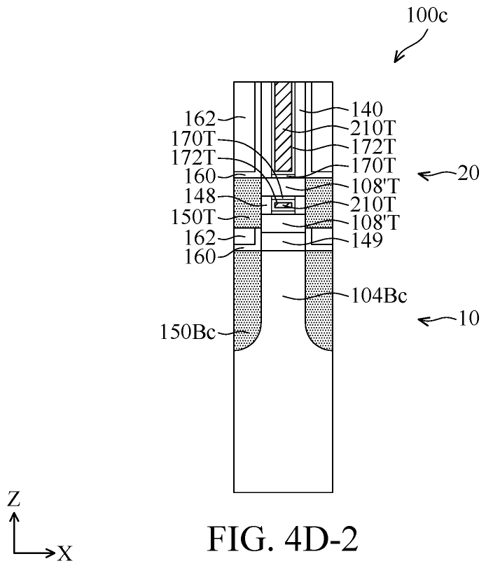

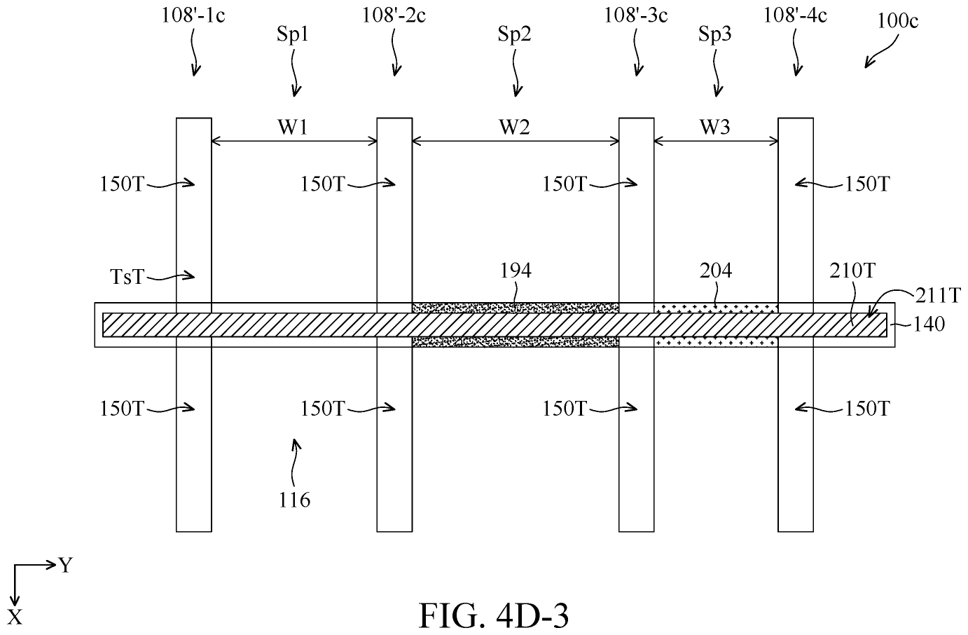

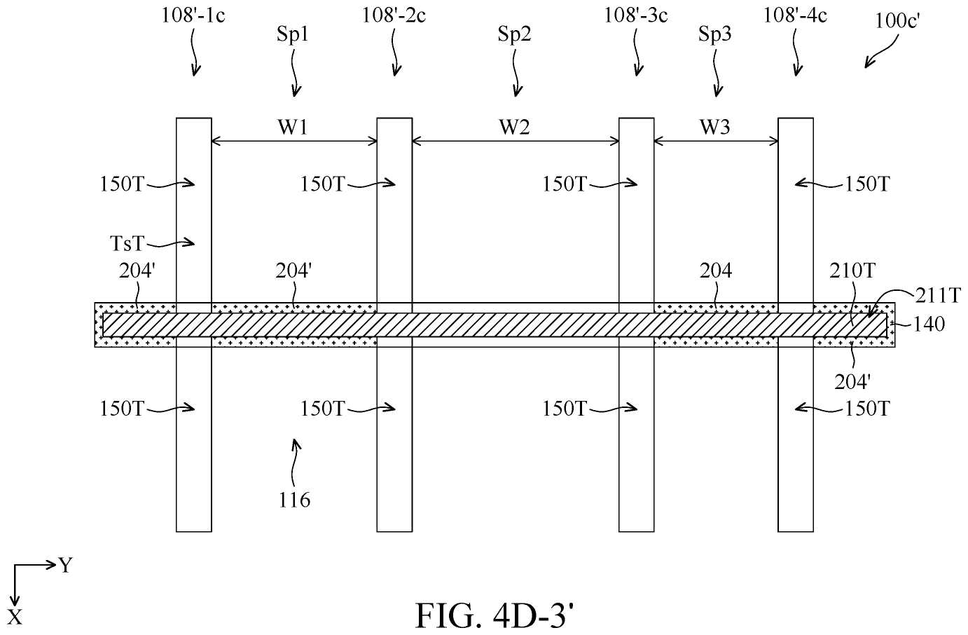

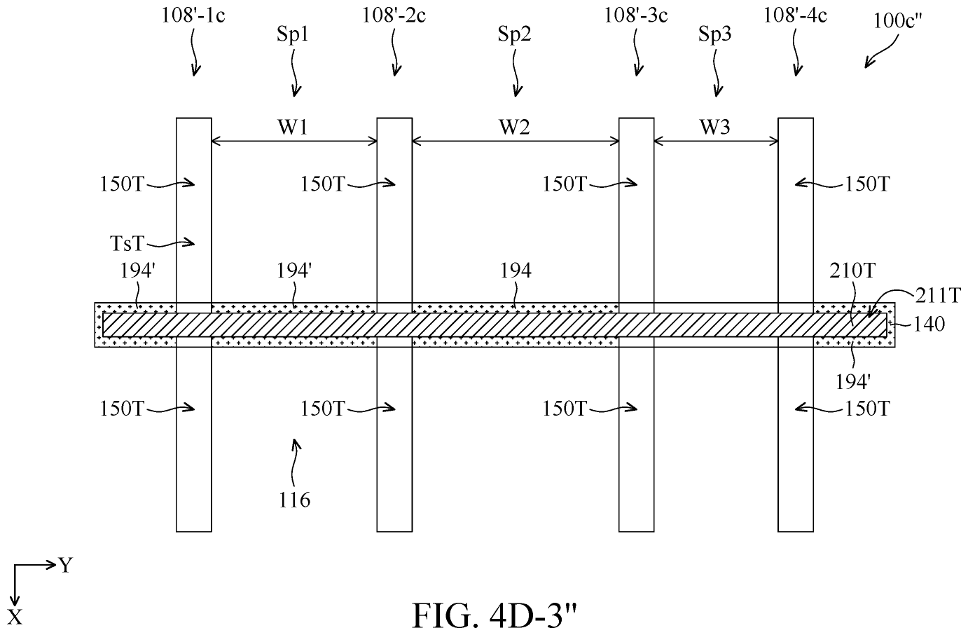

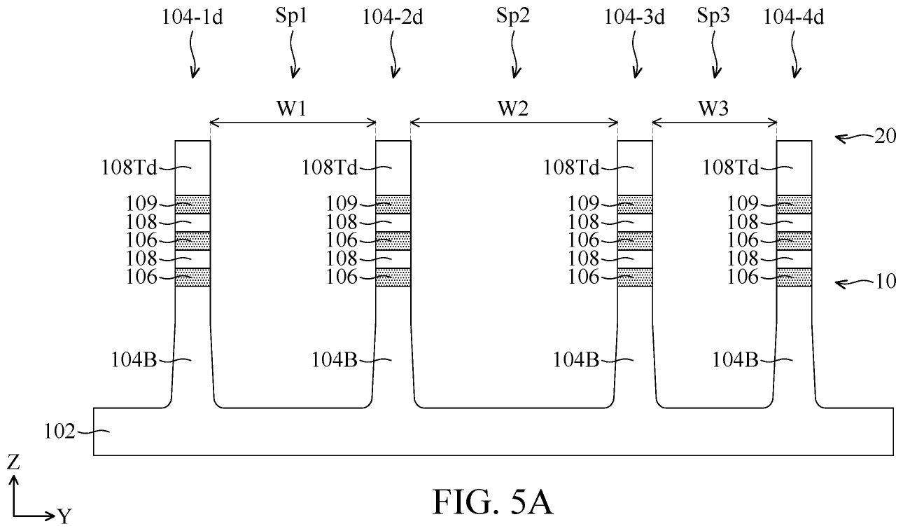

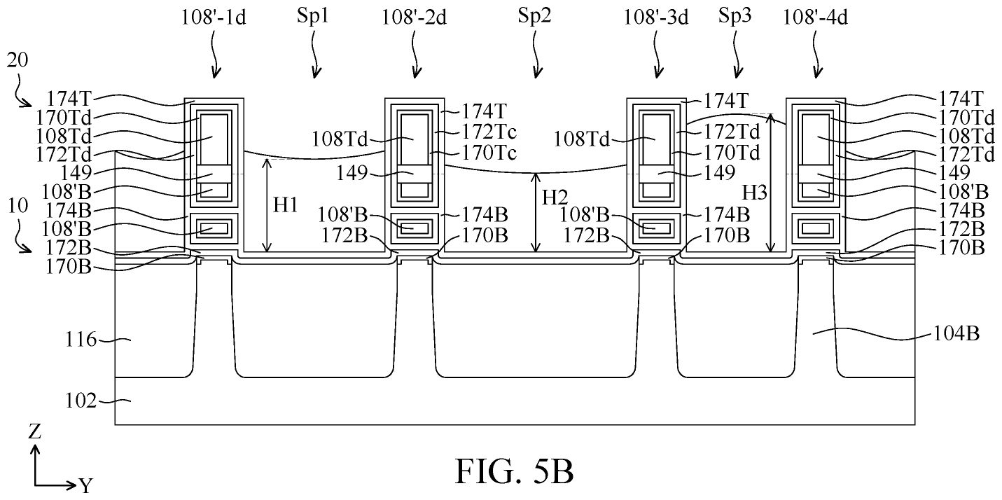

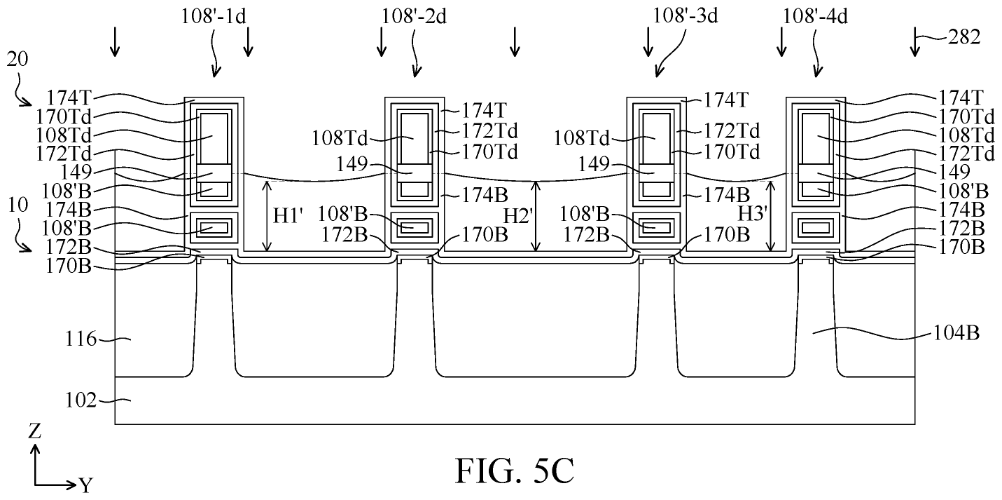

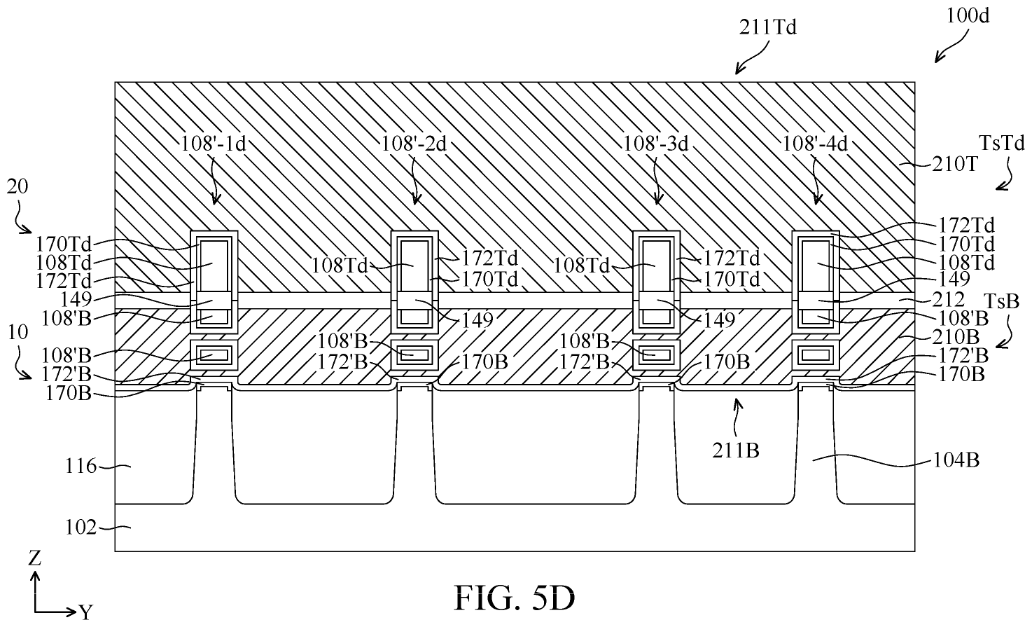

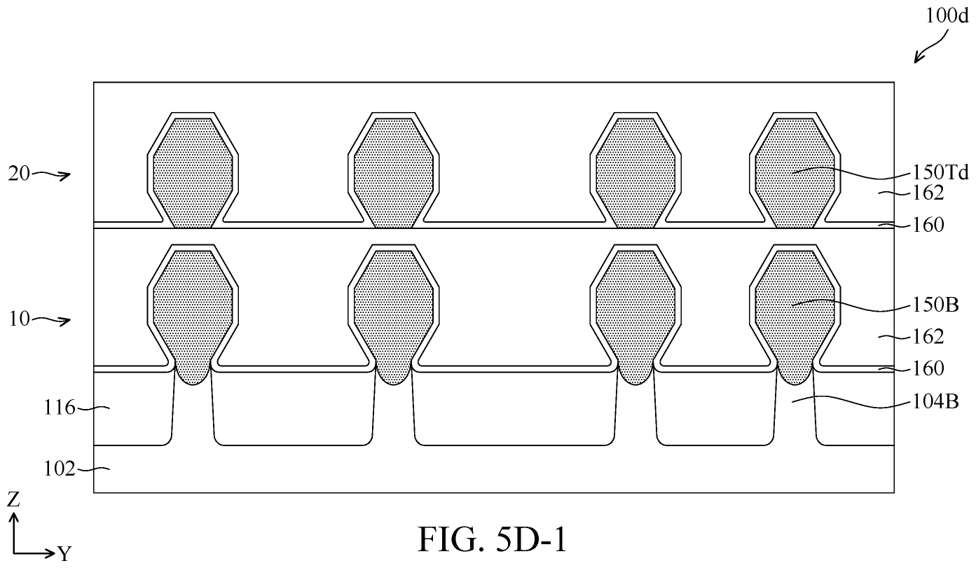

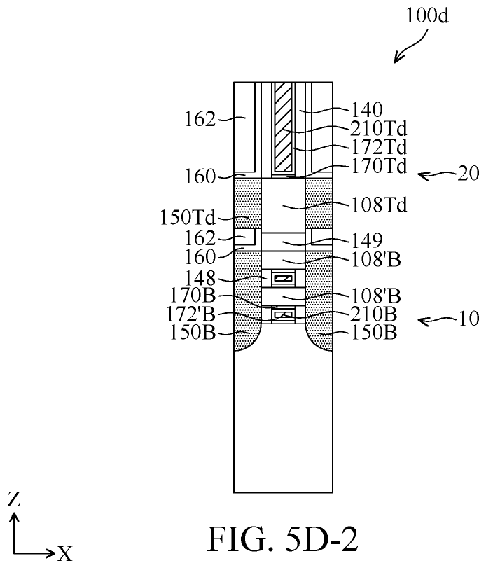

FIGS. 4A to 4D illustrate cross-sectional views of intermediate stages of manufacturing a semiconductor structure in accordance with some embodiments.

FIGS. 4D-1 and 4D-2 illustrate cross-sectional views of the semiconductor structure 100c along the Y direction at the source/drain region and at the X direction at the channel structure 108′-1c, respectively, in accordance with some embodiments.

FIG. 4D-3, 4D-3′, and 4D-3″ illustrate the top view of the semiconductor structure when formed by the processes shown in FIGS. 1H to 1L, 2A to 2B, and 3A to 3B, respectively, in accordance with some embodiments.

FIGS. 5A to 5D illustrate cross-sectional views of intermediate stages of manufacturing a semiconductor structure in accordance with some embodiments.

FIGS. 5D-1 and 5D-2 illustrate cross-sectional views of the semiconductor structure 100d along the Y direction at the source/drain region and at the X direction at the channel structure 108′-1c, respectively, in accordance with some embodiments.

FIG. 5D-3, 5D-3′, and 5D-3″ illustrate the top view of the semiconductor structure when formed by the processes shown in FIGS. 1H to 1L, 2A to 2B, and 3A to 3B, respectively, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, so that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numerals are used to designate like elements. It should be understood that additional operations can be provided before, during, and after the method, and some of the operations described can be replaced or eliminated for other embodiments of the method.

The nanostructure transistors (e.g. nanosheet transistors, nanowire transistors, multi-bridge channel transistors, nano-ribbon FET, and gate all around (GAA) transistors) described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the nanostructures.

The fin structures described below may be patterned by any suitable method. For example, the fin structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

Embodiments of semiconductor structures and methods for forming the same are provided. The semiconductor structures may include a number of complementary field-effect transistor (CFET) structures, and each of the CFET structures may include a set of transistors, including an n-type transistor and a p-type transistor vertically stacked. More specifically, each of the CFET structures includes a first type of transistor formed in the bottom device region and a second type of transistor formed in the top device region, which is located above the bottom device region. The first type and the second type of transistors may individually include channel structures, such as nanostructures, nanosheet structures, nanowires, or fin structures, formed over a substrate and a gate structure formed around the channel structures. In addition, the formation of the gate structures may include forming gate dielectric material in both the bottom device region and the top device region and treating the gate dielectric material in at least one (e.g. the bottom device region) or both device regions, so that the threshold voltage of the resulting first type and the second type of transistors in the bottom device region and the top device region may be different.

During the formation of the gate structures in the bottom device region and the top device region, a dummy material may be used to protect the structure in the bottom device region. In particular, the spaces between the channel structures of the neighboring CFET structures are first fully filled by the dummy material, and the dummy material is etched back to protect the structures in the bottom device region while the structures in the top device region are exposed. Accordingly, the gate structures in the bottom device region and the top device region may be formed and adjusted separately.

However, when a number of CFET structures with various lateral spacing (e.g. distances between the channel structures of neighboring CFET structures) are formed, the height of the dummy material may not be uniformed due to different etching rate at different spacing during the etching-back process. Therefore, an additional implantation process may be performed to adjust the etching rates of the dummy material at different regions, so that the dummy material for protecting the bottom device region may be substantially level at different regions. Accordingly, the performance of the resulting CFET structures and the yield of its manufacturing processes may be improved.

FIGS. 1A to 1P, 1A-1 to 1D-1, and 1A-2 to 1D-2 illustrate cross-sectional views of intermediate stages of manufacturing a semiconductor structure 100 in accordance with some embodiments. FIG. 1A-3 illustrates a diagrammatic perspective view of the intermediate stage of manufacturing the semiconductor structure 100 shown in FIGS. 1A-1, 1A-2, and 1A-3 in accordance with some embodiments. FIG. 1A-4 illustrates a diagrammatic top view of the intermediate stage of manufacturing the semiconductor structure 100 shown in FIGS. 1A, 1A-1, 1A-2, and 1A-3 in accordance with some embodiments. FIG. 1A-4 has been simplified for the sake of clarity to better understand the inventive concepts of the present disclosure. For a better understanding of the semiconductor structure 100, the X-Y-Z coordinate reference is provided in the figures.

More specifically, FIGS. 1A to 1P, 1A-1 to 1D-1, and 1A-2 to 1D-2 illustrate cross-sectional views of intermediate stages of manufacturing the semiconductor structure 100 shown along line Y_{MG}-Y_{MG}′ (i.e. in the Y direction), Y_{SD}-Y_{SD}′ (i.e. in the Y direction), and X₁₀₄₋₁-X₁₀₄₋₁′ (i.e. in the X direction) in FIGS. 1A-3 and 1A-4, respectively, in accordance with some embodiments. The X-axis and Y-axis are generally orientated along the lateral (e.g. horizontal) directions that are parallel to the main surface of a substrate 102 in the semiconductor structure 100. The Y-axis is transverse (e.g., substantially perpendicular) to the X-axis. The Z-axis is generally oriented along the vertical direction that is perpendicular to the main surface of the substrate 102 (e.g. the X-Y plane).

First, a first semiconductor stack is formed in the bottom device region 10 over the substrate 102, a middle layer 109 is formed over the first semiconductor stack, and a second semiconductor stack is formed in the top device region 20 over the middle layer 109 in accordance with some embodiments.

The substrate 102 may be a semiconductor wafer such as a silicon wafer. Alternatively or additionally, the substrate 102 may include elementary semiconductor materials, compound semiconductor materials, and/or alloy semiconductor materials. Elementary semiconductor materials may include, but are not limited to, crystal silicon, polycrystalline silicon, amorphous silicon, germanium, and/or diamond. Compound semiconductor materials may include, but are not limited to, silicon carbide, gallium arsenic, gallium phosphide, indium phosphide, indium arsenide, and/or indium antimonide. Alloy semiconductor materials may include, but are not limited to, SiGe, GaAsP, AlInAs, AlGaAs, GaInAs, GaInP, and/or GaInAsP.

In some embodiments, both of the first semiconductor stack and the second semiconductor stack include first semiconductor material layers 106 and second semiconductor material layers 108 alternately stacked. In some embodiment, the first semiconductor material layers 106 and the second semiconductor material layers 108 are made of different semiconductor materials. In some embodiments, the middle layer 109 and the first semiconductor material layers 106 are made of the same material. In some embodiments, the first semiconductor material layers 106 and the middle layer 109 are made of SiGe, and the second semiconductor material layers 108 are made of silicon. It should be noted that the semiconductor stacks may include less or more of the first semiconductor material layers 106 and the second semiconductor material layers 108 shown in FIGS. 1A, 1A-1, 1A-2, 1A-3, and 1A-4. For example, each of the semiconductor stacks may include two to five of the first semiconductor material layers 106 and two to five of the second semiconductor material layers 108.

The first semiconductor material layers 106, the middle layer 109, and the second semiconductor material layers 108 may be formed by using low-pressure chemical vapor deposition (LPCVD), epitaxial growth process, another suitable method, or a combination thereof. In some embodiments, the epitaxial growth process includes molecular beam epitaxy (MBE), metal organic chemical vapor deposition (MOCVD), or vapor phase epitaxy (VPE).

Afterwards, the first semiconductor stack, the middle layer 109, the second semiconductor stack, and the substrate are patterned to form fin structures 104-1, 104-2, 104-3, and 104-2, as shown in FIGS. 1A, 1A-1, 1A-2, 1A-3, and 1A-4 in accordance with some embodiments. In some embodiments, the patterning process includes forming a mask structure over the second semiconductor stacks and etching the two semiconductor stacks, the middle layer 109, and the underlying substrate 102 through the mask structure.

The fin structures 104-1 to 104-4 may individually extend lengthwise in the X direction and may be aligned with each other in the Y direction. In addition, the space Sp1 between the fin structures 104-1 and 104-2 has a width W1, the space Sp2 between the fin structures 104-2 and 104-3 has a width W2, and the space Sp3 between the fin structures 104-3 and 104-4 has a width W3. In some embodiments, the width W2 is greater than the width W1, and the width W1 is greater than the width W3. In some embodiments, the width W1 is in a range from about 25 nm to about 35 nm. In some embodiments, the width W2 is in a range from about 30 nm to about 50 nm. In some embodiments, the width W3 is in a range from about 15 nm to about 25 nm.

In some embodiments, each of the fin structures 104-1 to 104-4 includes the first semiconductor stack formed in the bottom device region 10, the second semiconductor stack formed in the top device region 20, the middle layer 109 separating the first and second semiconductor stacks, and the base fin structure 104B underneath the bottom device region 10 in accordance with some embodiments. In addition, the bottom device region 10 vertically overlaps the top device region 20 in accordance with some embodiments.

After the fin structures 104-1 to 104-4 are formed, an isolation structure 116 is formed around the fin structures 104-1 to 104-4, and a dummy gate structure 130 is formed across the fin structures 104-1 to 104-4, as shown in FIGS. 1B, 1B-1, and 1B-2, and 1B-3 in accordance with some embodiments. The isolation structure 116 is configured to electrically isolate active regions (e.g. the fin structures 104-1 to 104-4) of the semiconductor structure and is also referred to as shallow trench isolation (STI) feature in accordance with some embodiments.

More specifically, an insulating layer may be formed around and covering the fin structures 104-1 to 104-4, and the insulating layer may be recessed to form the isolation structure 116 with the fin structures 104-1 to 104-4 protruding from the top surface of the isolation structure 116. In some embodiments, the insulating layer is made of silicon oxide, silicon nitride, silicon oxynitride (SiON), another suitable insulating material, or a combination thereof. In addition, liner layers (not shown) may be formed before forming the insulating layer, and the liner layers may also be recessed with the insulating layer to form the isolation structure 116. In some embodiments, the liner layers include multiple dielectric material layers.

The dummy gate structure 130 may be used to define the channel regions of the resulting semiconductor structure 100. In some embodiments, the dummy gate structure 130 includes a dummy gate dielectric layer 132 and a dummy gate filling layer 134. In some embodiments, the dummy gate dielectric layer 132 is made of one or more dielectric materials, such as silicon oxide, silicon nitride, silicon oxynitride (SiON), HfO₂, HfZrO, HfSiO, HfTiO, HfAlO, or a combination thereof. In some embodiments, the dummy gate dielectric layer 132 is formed using thermal oxidation, CVD, ALD, physical vapor deposition (PVD), another suitable method, or a combination thereof. In some embodiments, the dummy gate filling layer 134 is made of conductive material includes polycrystalline-silicon (poly-Si), poly-crystalline silicon-germanium (poly-SiGe), or a combination thereof. In some embodiments, the dummy gate filling layer 134 is formed using CVD, PVD, or a combination thereof. In some embodiments, a hard mask layer 136 is formed over the dummy gate filling layer 134. In some embodiments, the hard mask layer 136 includes multiple layers, such as an oxide layer and a nitride layer. In some embodiments, the oxide layer is silicon oxide, and the nitride layer is silicon nitride.

After the dummy gate structure 130 is formed, a spacer layer is formed to cover the top surfaces and the sidewalls of the dummy gate structures 130 and the fin structures 104-1 to 104-4, and an etching process is performed to form gate spacers 140 and source/drain recesses 144 adjacent to the gate spacers 140, as shown in FIGS. 1B, 1B-1, 1B-2, and 1B-3 in accordance with some embodiments. FIG. 1B-3 illustrates a diagrammatic top view of the intermediate stage of the semiconductor structure 100 shown in FIGS. 1B to 1B-2 in accordance with some embodiments.

In some embodiments, the spacer layer is made one or more dielectric materials. The dielectric materials may include silicon oxide (SiO₂), silicon nitride (SiN), silicon carbide (SiC), silicon oxynitride (SiON), silicon carbon nitride (SiCN), silicon oxide carbonitride (SiOCN), and/or a combination thereof. After the spacer layer is formed, an etching process is performed to form the gate spacers 140, which may be configured to separate source/drain structures (formed afterwards) from the gate structure formed afterwards. In addition, the portions of the fin structures 104-1 to 104-4 not covered by the dummy gate structure 130 and the gate spacers 140 are etched to form the source/drain recesses 144 during the etching process in accordance with some embodiments. The etching process may be an anisotropic etching process, such as dry plasma etching, and the dummy gate structure 130 and the gate spacers 140 may be used as etching masks during the etching process. In some embodiments, the isolation structure 116 is also slightly etched during the etching process.

After the source/drain recesses 144 are formed, inner spacers 148 are formed in both the bottom device region 10 and the top device region 20, and the middle layers 109 are replaced by isolation layers 149, as shown in FIGS. 1C, 1C-1, and 1C-2 in accordance with some embodiments. In addition, bottom source/drain structures 150B are formed in the bottom device region 10, top source/drain structures 150T are formed in the top device region 20, and contact etch stop layers 160 and interlayer dielectric layers 162 are formed in both bottom device region 10 and top device region 20 over the source/drain structures 150B and 150T in accordance with some embodiments.

The inner spacers 148 may be formed by laterally recceing the first semiconductor material layers 106 exposed by the source/drain recesses 144 to form notches and forming the inner spacers 148 in the notches. In addition, the middle layers 109 are replaced by the isolation layers 149. In some embodiments, the inner spacers 148 and the isolation layers 149 are made of the same dielectric material. In some embodiments, the inner spacers 148 and the isolation layers 149 are made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), or a combination thereof.

The source/drain structures 150B formed in the bottom device region 10 of the source/drain recesses 144 and source/drain structures 150T formed in the top device region 20 of the source/drain recesses 144 may be different types of source/drain structures. In some embodiments, the source/drain structures 150B and 150T are formed using separated epitaxial growth processes, such as MBE, MOCVD, VPE, other applicable epitaxial growth process, or a combination thereof. In some embodiments, the source/drain structures 150B and 150T are made of any applicable material, such as Ge, Si, GaAs, AlGaAs, SiGe, GaAsP, SiP, SiC, SiCP, or a combination thereof. In some embodiments, the source/drain structures 150B and 150T are in-situ doped during the epitaxial growth process. In some embodiments, the source/drain structures 150B and 150T are doped in one or more implantation processes after the epitaxial growth process. The source/drain structures described herein may refer to a source or a drain, individually or collectively dependent upon the context.

The contact etch stop layers (CESL) 160 are conformally formed to cover the source/drain structures 150B and 150T, the interlayer dielectric (ILD) layers 162 are formed over the contact etch stop layers 160 in both the bottom device region 10 and the top device region 20, respectively, as shown in FIG. 1C-1 in accordance with some embodiments. In some embodiments, the contact etch stop layers 160 are made of a dielectric materials, such as silicon nitride, silicon oxide, silicon oxynitride, another suitable dielectric material, or a combination thereof. The dielectric material for the contact etch stop layers 160 may be conformally deposited over the semiconductor structure by performing CVD, ALD, other application methods, or a combination thereof.

The interlayer dielectric layers 162 may include multilayers made of multiple dielectric materials, such as silicon oxide, silicon nitride, silicon oxynitride, phosphosilicate glass (PSG), borophosphosilicate glass (BPSG), or other applicable low-k dielectric materials. The interlayer dielectric layers 162 may be formed by chemical vapor deposition (CVD), physical vapor deposition, (PVD), atomic layer deposition (ALD), or other applicable processes.

After the contact etch stop layers 160 and the interlayer dielectric layers 162 at the top device region 20 are deposited, a planarization process such as CMP or an etch-back process is performed until the dummy gate filling layer 134 is exposed, as shown in FIG. 1C-2 in accordance with some embodiments.

Next, the dummy gate structures 130, the first semiconductor material layers 106 in both the bottom device region 10 and the top device region 20 are removed to form gate trenches 166, as shown in FIGS. 1D, 1D-1, and 1D-2 in accordance with some embodiments. More specifically, the dummy gate structures 130 and the first semiconductor material layers 106 are removed to form channel structures (e.g. nanostructures) 108′-1, 108′-2, 108′-3, and 108′-4 with the second semiconductor material layers 108 of the fin structures 104-1 to 104-4 in accordance with some embodiments. In addition, each of the channel structures 108′-1 to 108′-4 includes channel layers 108′B in the bottom device region 10 and the channel layers 108′T in the top device region 20 in accordance with some embodiments. Although not clearly shown in the figures, the channel layers 108′B and 108′D and the base fin structures 104B may have rounded corners.

As shown in FIGS. 1D and 1D-2, the channel layers 108′B vertically overlaps and aligned with the channel layers 108′T in accordance with some embodiments. More specifically, the top surface of the topmost channel layer in the channel layers 108′B in the bottom device region 10 is covered by the isolation layer 149, and the bottom surface of the bottommost channel layer of the channel layers 108′T is covered by the isolation layer 149, as shown in FIGS. 1D and 1D-2 in accordance with some embodiments. That is, the isolation layer 149 is vertically sandwiched between the topmost channel layer of the channel layers 108′B and the bottommost channel layer of the channel layers 108′T in accordance with some embodiments.

After the channel layers 108′B and 108′T are formed, interfacial layers 170 (including portions 170B and 170T), gate dielectric layers 172 (including portions 172B and 172T), and dipole layers 174 (including portions 174B and 174T) are formed around the channel layers 108′B and 108′T, as shown in FIG. 1E in accordance with some embodiments. More specifically, the portion 170B of the interfacial layers 170, the portion 172B of the gate dielectric layers 172, and the portion 174B of the dipole layers 174 are formed to wrap around the channel layers 108′B in the bottom device region 10 and to cover the base fin structure 104B, and the portion 170T of the interfacial layers 170, the portion 172T of the gate dielectric layers 172, and the portion 174T of the dipole layers 174 are formed to wrap around the channel layers 108′T in the top device region 20 in accordance with some embodiments.

In some embodiments, the portions 170B and 170T of the interfacial layers 170 are made of the same material using the same deposition process. In some embodiments, the portions 172B and 172T of the gate dielectric layers 172 are made of the same material using the same deposition process. In some embodiments, the portions 174B and 174T of the dipole layers 174 are made of the same material using the same deposition process.

The interfacial layers 170 are configured to improve the interfaces between the channel layers 108′T and 108′B and the gate dielectric layers 172 formed afterwards. In addition, the interfacial layers 170 may be able to help suppressing the mobility degradation of charge carries in the channel layers 108′T and 108′B that serve as channel regions of the transistors. In some embodiments, the interfacial layers 170 are oxide layers formed by performing a thermal process. In some embodiments, the interfacial layers 170 have a thickness in a range from about 0.5 nm to about 2 nm.

After the interfacial layers 170 are formed, the gate dielectric layers 172 are conformally formed to cover the interfacial layers 170 and the bottom surface and the sidewalls of the gate trenches 166 in accordance with some embodiments. In some embodiments, the gate dielectric layers 172 are made of a dielectric material, such as HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, La₂O₃—Al₂O₃, LaO, other applicable high-k dielectric materials, or a combination thereof. In some embodiments, the gate dielectric layers 172 are formed using CVD, ALD, other applicable methods, or a combination thereof. In some embodiments, the gate dielectric layers 172 have a thickness in a range from about 1 nm to about 5 nm.

After the gate dielectric layers 172 are formed, the dipole layers 174 are formed over and in physical contact with the top surface of the gate dielectric layers 172 in both the bottom device region 10 and the top device region 20 in accordance with some embodiments. The dipole layers 174 are configured to modify the gate dielectric layer 172 to augment or reduce the effect of the voltage applied to a gate filling in turning on or turning off the resulting transistors. That is, the threshold voltages of the resulting transistors may be adjusted. In some embodiments, the dipole layers 174 are made of Al₂O₃, BeO, V₂O₅, TiO₂, Ga₂O₃, NiO, Nb₂O₅, Ta₂O₅, Sc₂O₃, Er₂O₃, Gd₂O₃, Eu₂O₃, Lu₂O₃, Y₂O₃, La₂O₃, CaO, SrO, BaO₃, ZnO, In₂O₃, or the like.

Afterwards, a dummy material 180 is formed over and between the channel structures 108′-1 to 108′-4, as shown in FIG. 1F in accordance with some embodiments. The dummy material 180 is configured to cover the bottom device region 10 in subsequent processes, so that the gate stacks formed in the bottom device region 10 and the top device region 20 may have different electrical properties as designed.

As shown in FIG. 1F, the spaces Sp1, Sp2, and Sp3 between the channel structures 108′-1 to 108′-4 are completely filled with the dummy material 180 in accordance with some embodiments. In some embodiments, the dummy material 180 is SiO₂, SiOC, SiOCN, or the like. The dummy material 180 may be formed by performing a CVD process or a spin-on-glass process. As shown in FIG. 1F, the top surface of the dummy material 180 is not flat in accordance with some embodiments. Since additional implantation and etching processes will be performed to adjust the height of the dummy material afterwards, additional polishing process, such as a CMP process, may not be required.

Afterwards, a first etching process 182 is performed to partially remove the dummy material 180, as shown in FIG. 1G in accordance with some embodiments. More specifically, the upper portions of the dummy material 180 over the channel structures 108′-1 to 108′-4 and in the top device regions 20 in the spaces Sp1, Sp2, and Sp3 are etched in accordance with some embodiments. In addition, since the spaces Sp1, Sp2, and Sp3 between the channel structures 108′-1 to 108′-4 are different, the etching rates of the dummy material 180 in these spaces may also different. For example, since the width W2 of the space Sp2 is wider than the width W1 of the space Sp1, the etching rate of the dummy material 180 in the space Sp2 is greater than the etching rate of the dummy material 180 in the space Sp1 in accordance with some embodiments. In addition, since the width W1 of the space Sp1 is wider than the width W3 of the space Sp3, the etching rate of the dummy material 180 in the space Sp1 is greater than the etching rate of the dummy material 180 in the space Sp3 in accordance with some embodiments. Since the original top surface of the dummy material 180 is not flat and the etching rates at different regions are different, the dummy material 180 have different heights after the first etching process 182 is performed.

As shown in FIG. 1G, the dummy material 180 at the space Sp1 has a height H1, the dummy material 180 at the space Sp2 has a height H2, and the dummy material 180 at the space Sp3 has a height H3 after the first etching process 182 is performed in accordance with some embodiments. In addition, the height H3 is higher than the height H1, and the height H1 is higher than the height H2. In some embodiments, the lowest points of the top surfaces of the dummy material 180 in the spaces Sp1, Sp2, and Sp3 are all higher than the bottom surface of the isolation layer 149. In some embodiments, the lowest points of the top surfaces of the dummy material 180 in the spaces Sp1 and Sp3 are both higher than the top surface of the isolation layer 149, while the lowest point of the top surface of the dummy material 180 in the space Sp2 is slightly lower than the top surface of the isolation layer 149.

In some embodiments, the isolation structure 149 has a thickness T149, and the lowest point of the top surface of the dummy material 180 in the space Sp2 is lower than the top surface of the isolation layer 149 for about ⅙ to about ⅘ of the thickness T149. In some embodiments, the lowest point of the top surface of the dummy material 180 in the space Sp2 is lower than the top surface of the isolation layer 149 for about 2.5 nm to about 12.5 nm.

In some embodiments, the first etching process 182 is a dry etching process or a wet etching process. In some embodiments, the first etching process 182 is a dry etching process using etchants such as HF and NH₃. In some embodiments, the ratio of HF to NH₃ is in a range from about 1:1 to 1:4. In some embodiments, the ratio of HF to NH₃ is in a range from about 1:0.2 to 1:8. In some embodiments, the first etching process 182 is a wet etching process using etchants such as HF and D.I. water. In some embodiments, the ratio of HF to D.I. water is in a range from about 1:1 to 1:1000.

After the first etching process 182 is performed, a mask structure 184 is formed over the dummy material 180 and the channel structures 108′-1 to 108′-4, as shown in FIG. 1H in accordance with some embodiments. In addition, an opening 186 is formed in the mask structure 184, so that the dummy material 180 in the space Sp2 is exposed in accordance with some embodiments. The mask structure 184 may include a photoresist layer.

Next, an implantation process 190 is performed to from a doped region 192 in the exposed portion of the dummy material 180 in the space Sp2, and the mask structure 184 is removed after the implantation process 190 is performed, as shown in FIG. 1I in accordance with some embodiments. The doped region 192 is configured to slow down the etching rate during the etching process performed afterwards, so that the height of the dummy material 180 at the spaces with different widths may still have substantially the same heights after the etching process. In some embodiments, the doped region 192 has a thickness (i.e. in the Z direction) in a range from about 0.5 nm to about 10 nm.

In some embodiments, the implantation process 190 includes implanting first dopants into the portion of the dummy material 180 in the space Sp2, so that the doped region 192 is formed in the exposed upper portion of the dummy material 180 located in the space Sp2. In some embodiments, the implantation process 190 includes using SiF₄, CO₂, CO, or a combination thereof. In some embodiments, the first dopants include Si, C, or a combination thereof. In some embodiments, the doped region 192 includes a single type of dopants, such as C or Si. In some embodiments, the doped region 192 includes two types of dopants, such as Si and C, Ge and Si, or Ge and C. In some embodiments, the dopant concentration in the doped region 192 is in a range from about 1E+14 to about 1E+16/cm². As described previously, the doped region 192 is formed in the dummy material 180 in the space Sp2 to slow down the etching rate at this region. Therefore, the dopant concentration should be high enough to achieve the designed etching rate. On the other hand, the dopant concentration should not be too high or the implanted species may become particles and therefore undermined the manufacturing processes. In some embodiments, the energy level used in the implantation process 190 is in a range from about 1 keV to about 8 keV.

In some embodiments, the implantation process 190 is performed at a relatively high temperature in a range from about 300° C. to about 1000° C., so that the implantation efficiency may be improved. In some other embodiments, the structure is not heated during the implantation process 190, but an annealing process is performed after the implantation process 190 is performed. In some embodiments, the annealing process is performed under a temperature in a range from about 500° C. to about 1000° C. The annealing process may also help to improve the implantation efficiency.

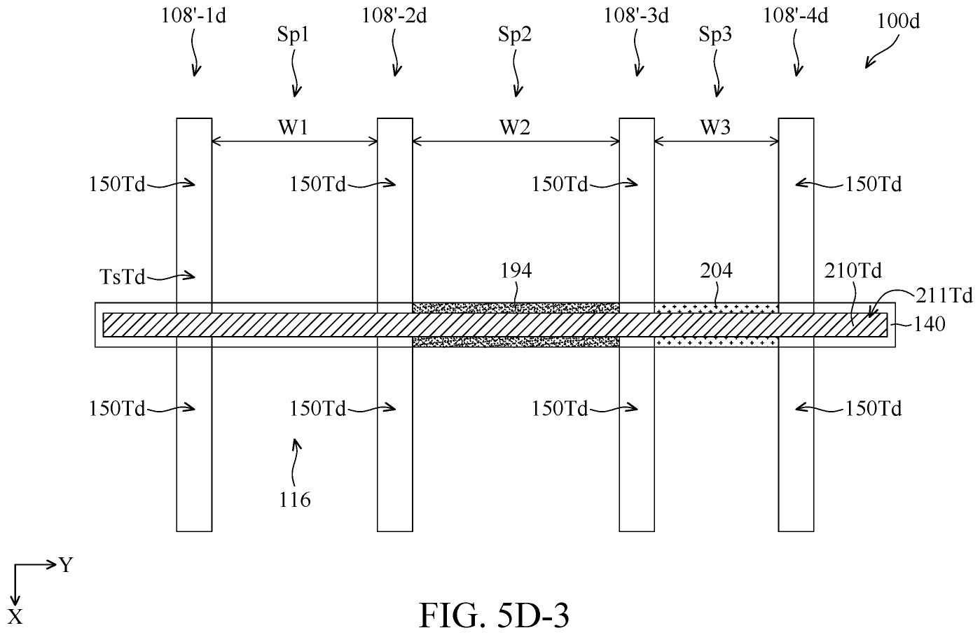

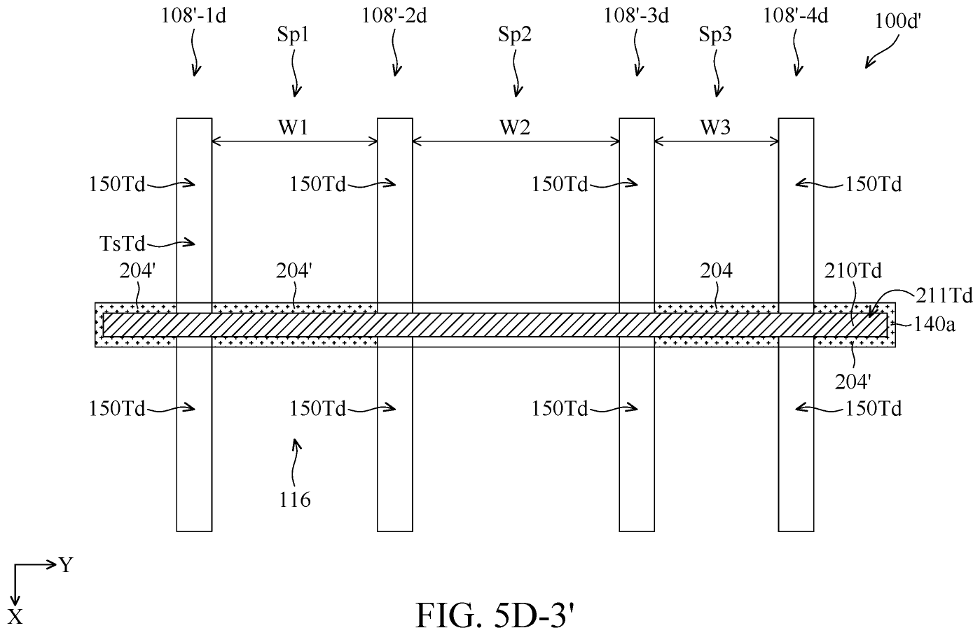

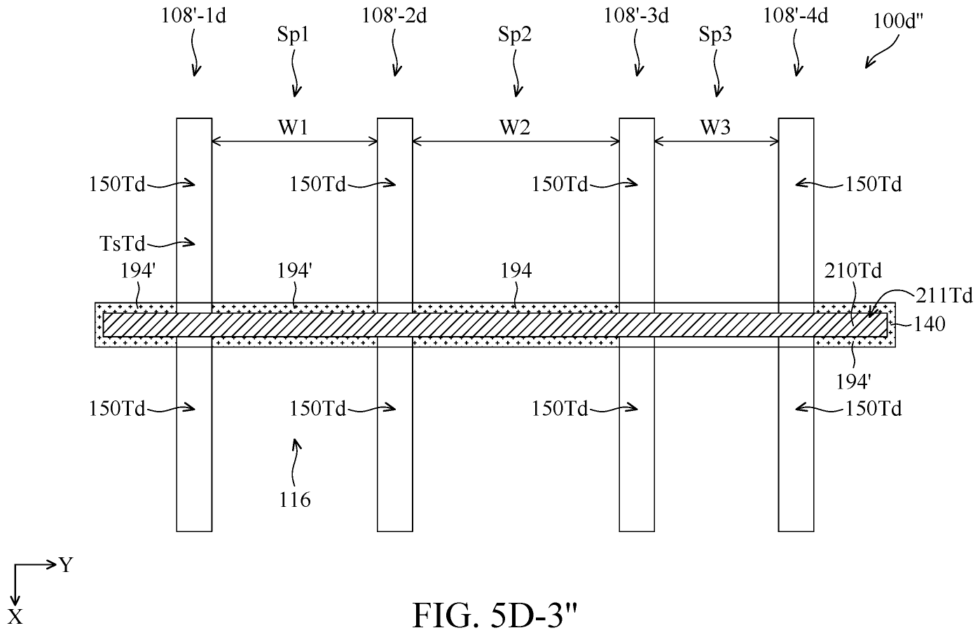

During the implantation process 190, some dopants may also be doped into the gate spacers 140 exposed by the opening 186, so that doped regions 194 may also be formed in the gate spacers 140 in accordance with some embodiments. FIG. 11-1 illustrates a diagrammatic top view of an intermediate stage of the semiconductor structure 100 shown in FIG. 1I in accordance with some embodiments. FIG. 11-2 illustrates a cross-sectional view of an intermediate stage of the semiconductor structure 100 shown alone line X_{Sp2} to X_{Sp2}′ in FIG. 11-1 in accordance with some embodiments. As shown in FIG. 11-2, the dopants used in the implantation process 190 are also implanted into the upper portions of the gate spacers 140 to form the doped regions 194 in accordance with some embodiments. Since both the doped regions 192 and 194 are formed by the implantation process 190, the dopants in the doped regions 194 are the same as those in the doped region 192.

After the implantation process 190 is performed, a mask structure 196 is formed over the dummy material 180 and the channel structures 108′-1 to 108′-4, as shown in FIG. 1J in accordance with some embodiments. In addition, an opening 198 is formed in the mask structure 196, so that the dummy material 180 in the space Sp3 is exposed in accordance with some embodiments. The mask structure 196 may include a photoresist layer.

Next, an implantation process 200 is performed to from a doped region 202 in the exposed portion of the dummy material 180 in the space Sp3, and the mask structure 196 is removed after the implantation process 200 is performed, as shown in FIG. 1K in accordance with some embodiments. The doped region 202 is configured to speed up the etching rate during the etching process performed afterwards, so that the height of the dummy material 180 at the spaces with different widths may still have substantially the same heights after the etching process. In some embodiments, the doped region 202 has a thickness (i.e. in the Z direction) in a range from about 0.5 nm to about 10 nm.

In some embodiments, the implantation process 200 includes implanting second dopants into the portion of the dummy material 180 in the space Sp3, so that the doped region 202 is formed in the exposed upper portion of the dummy material 180 located in the space Sp3. In some embodiments, the implantation process 200 includes using PH₃, CO₂, CO, or a combination thereof. In some embodiments, the second dopants include P, C, As, N, or a combination thereof. In some embodiments, the doped region 202 includes two types of dopants, such as Ge and C, N and Si, N and C, As and C, or P and C. In some embodiments, the dopant concentration in the doped region 202 is in a range from about 1E+14 to about 1E+16/cm². As described previously, the doped region 202 is formed in the dummy material 180 in the space Sp3 to speed up the etching rate at this region. Therefore, the dopant concentration should be high enough to achieve the designed etching rate. On the other hand, the dopant concentration should not be too high or the implanted species may become particles and therefore undermined the manufacturing processes. In some embodiments, the energy level used in the implantation process 200 is in a range from about 1 keV to about 8 keV.

During the implantation process 200, some dopants may also be doped into the gate spacers 140 exposed by the opening 198, so that doped regions 204 may also be formed in the gate spacers 140 in accordance with some embodiments. FIG. 1K-1 illustrates a diagrammatic top view of an intermediate stage of the semiconductor structure 100 shown in FIG. 1K in accordance with some embodiments. FIG. 1K-2 illustrates a cross-sectional view of an intermediate stage of the semiconductor structure 100 shown alone line X_{Sp3} to X_{Sp3}′ in FIG. 1K-1 in accordance with some embodiments. As shown in FIG. 1K-2, the dopants used in the implantation process 200 are also implanted into the upper portions of the gate spacers 140 to form the doped regions 204 in accordance with some embodiments. Since both the doped regions 202 and 204 are formed by the implantation process 200, the dopants in the doped regions 204 are the same as those in the doped region 202. In some embodiments, the doped regions 204 are separated from the doped regions 194 by un-doped regions, as shown in FIG. 1K-1.

Afterwards, a second etching process 282 is performed to etch the dummy material 180, as shown in FIG. 1L in accordance with some embodiments. In some embodiments, the etchant used in the second etching process 282 is the same as the etchant used in the first etching process 182. More specifically, the portions of the dummy material 180 between the channel structures 108′-1 to 108′-4 are further etched during the second etching process 282 in accordance with some embodiments. In addition, since the doped region 192 is formed in the space Sp2 and the doped region 202 is formed in the space Sp3, the etching rates of the dummy material 180 during the second etching process 282 in these spaces can be substantially the same, although the spaces Sp1, Sp2, and Sp3 have different widths.

As shown in FIG. 1L, the dummy material 180 at the space Sp1 has a height H1′, the dummy material 180 at the space Sp2 has a height H2′, and the dummy material 180 at the space Sp3 has a height H3′ after the second etching process 282 is performed, and the heights H1′, H2′, and H3′ are substantially the same in accordance with some embodiments. That is, the difference between the heights H3 and H3′ (e.g. the heights before and after the second etching process 282 is performed in the space Sp3) is greater than the difference between the heights H1 and H1′ (e.g. the heights before and after the second etching process 282 is performed in the space Sp2), and the difference between the heights H1 and H1′ is greater than the difference between the heights H2 and H2′ (e.g. the heights before and after the second etching process 282 is performed in the space Sp2) in accordance with some embodiments.

In some embodiments, the dummy material 180 in the spaces Sp1, Sp2, and Sp3 have curved top surfaces and has the lowest points (e.g. Z direction) at the middle portions (e.g. Y direction) of the spaces Sp1, Sp2, and Sp3. In some embodiments, the doped region 202 are completely removed during the second etching process 282, while the doped region 192 has a remaining portion after the second etching process 282 is performed. In some other embodiments, the doped region 202 also has a remaining portion after the second etching process 282 is performed. In some other embodiments, the doped region 192 is completely removed during the second etching process 282.

In some embodiments, the intersection points of the dummy material 180 and the dipole layers 174 are no lower than the bottom surface of the isolation layer 149 (i.e. the top surface of the topmost channel layer of the channel layers 108′B). More specifically, after the second etching process 282 is performed, the portions 174T of the dipole layers 174 in the top device region 20 are exposed, while the portions 174B of the dipole layers 174 in the bottom device region 10 are covered by the dummy material 180.

In some embodiments, the second etching process 282 is a dry etching process or a wet etching process. In some embodiments, the second etching process 282 is a dry etching process using etchants such as HF and NH₃. In some embodiments, the ratio of HF to NH₃ is in a range from about 1:1 to 1:4. In some embodiments, the ratio of HF to NH₃ is in a range from about 1:0.2 to 1:8. In some embodiments, the second etching process 282 is a wet etching process using etchants such as HF and D.I. water. In some embodiments, the ratio of HF to D.I. water is in a range from about 1:1 to 1:1000.

Next, the portions 174T of the dipole layers 174 in the top device region 20 are removed, as shown in FIG. 1M in accordance with some embodiments. The portions 174T of the dipole layers 174 may be removed by performing a dry etching process or a wet etching process.

Afterwards, the dummy material 180 is completely remove to expose the portions 174B of the dipole layers 174 in the bottom device region 10, as shown in FIG. 1N in accordance with some embodiments. In some embodiments, the dummy material 180 is removed by performing an etching process similar to the first etching process 182 and the second etching process 282.

After the dummy material 180 is removed, a treatment process is performed to form modified portions 172′B of the gate dielectric layer 172 in the bottom device region 10, and the dipole layers 174 are removed afterwards, as shown in FIG. 1O in accordance with some embodiments. More specifically, During the treatment process, the metal elements of the dipole layers 174 are driven (e.g. diffuse) into the portions 172B of the gate dielectric layers 172 in the bottom device region 10 to form modified portions 172′B. The metal elements driven into the portions 172B of gate dielectric layers 172 cause a dipole effect that augments or reduces the effect of the voltage applied to a gate filling in turning on or turning off the transistor formed in the bottom device region 10. That is, the effective work function of the resulting transistor is modulated, thereby increasing or decreasing the threshold voltage of the transistor formed in the bottom device region 10. In some embodiments, by treating the portions 172B of the gate dielectric layers 172 with the metal elements of the dipole layers 174 in the bottom device region 10, the threshold voltage of the resulting transistor in the bottom device region 10 is different from the threshold voltage of the resulting transistor in the top device region 20.

In some embodiments, the treatment process is an annealing process. In some embodiments, the annealing process is performed at a temperature in a range of about 400° C. to about 1000° C. In some embodiments, the annealing process is performed for about 0.5 sec to about 30 sec. After the treatment process, the portions 174B of the dipole layers 174 may be removed by performing an etching process, such as a dry etching process or a wet etching process.

In some other embodiments, the portions 172T of the gate dielectric layers 172 are also modified. For example, an additional dipole layer made of a material different from that the dipole layers 174 are made of may be formed over the portions 172T of the gate dielectric layers 172. Then, the portions 172T of the gate dielectric layers 172 may be modified by the additional dipole layer, and the additional dipole layer may be removed afterwards.

Next, gate structures 211B and 211T are formed in accordance with some embodiments. More specifically, a gate filling layer 210B is formed around the channel layers 108′B in the bottom device region 10, an isolation structure 212 is formed over the gate filling layer 210B, and a gate filling layer 210T is formed around the channel layers 108′T, as shown in FIGS. 1P, 1P-1, 1P-2, 1P-3, 1P-4, and 1P-5 in accordance with some embodiments. FIG. 1P-3 illustrates the top view of the semiconductor structure 100 in accordance with some embodiments. FIGS. 1P, 1P-1, and 1P-2 illustrate cross-sectional views of the semiconductor structure 100 shown along line Y_{MG}-Y_{MG}′ (i.e. in the Y direction), Y_{SD}-Y_{SD}′ (i.e. in the Y direction), and X_{108′-1}-X_{108′-1}′ (i.e. in the X direction) in FIG. 1P-3, respectively, in accordance with some embodiments. FIG. 1P-4 illustrates a cross-sectional view of the semiconductor structure 100 shown along line X_{Sp2} to X_{Sp2}′ in FIG. 1P-3 in accordance with some embodiments. FIG. 1P-5 illustrates a cross-sectional view of the semiconductor structure 100 shown alone line X_{Sp3} to X_{Sp3}′ in FIG. 1P-3 in accordance with some embodiments.

In some embodiments, the gate filling layers 210B and 210T are made of conductive materials, such as pure metal (e.g. Ti, Al, W, Ta . . . etc) or metal compound (e.g. TaN, TiN, TiAl, WN . . . etc). In some embodiments, the thickness of the gate filling layer is in a range from about 0.5 nm to about 5 nm. In some embodiments, the gate filling layers 210B and 210T are formed using CVD, ALD, electroplating, another applicable method, or a combination thereof. In some embodiments, a polishing process, such as a CMP process, is performed after the gate filling layer 210T is formed.

As shown in FIG. 1P, the gate structure 211B is formed in the bottom device region 10 and includes the portion 170B of the interfacial layer 170, the modified portion 172′B of the gate dielectric layer 172, and the gate filling layer 210B wrapping around the channel layers 108′B in accordance with some embodiments. In addition, the gate structure 211T is formed in the top device region 20 and includes the portion 170T of the interfacial layer 170, the portion 172T of the gate dielectric layer 172, and the gate filling layer 210T wrapping around the channel layers 108′T in accordance with some embodiments.

The isolation structure 212 is configured to separate the gate structure 211B in the bottom device region 10 and the gate structure 211T in the top device region 20. In some embodiments, the isolation structure 212 is made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), or a combination thereof. In some embodiments, the thickness of the isolation structure 212 is substantially equal to the thickness of the isolation layers 149.

As shown in FIGS. 1P, 1P-1, 1P-2, 1P-3, 1P-4, and 1P-5, the semiconductor structure 100 includes a numbers of complementary field-effect transistor (CFET) structures in accordance with some embodiments. In addition, each of the CFET structures includes transistors TsB (e.g. bottom transistors) in the bottom device region 10 and transistors TsT (e.g. top transistors) in the top device region 20 in accordance with some embodiments. In addition, the transistors TsT vertically overlaps the transistors TsB in accordance with some embodiments. In some embodiments, each of the transistors TsB includes the channel layers 108′B (e.g. bottom channel layers), the source/drain structures 150B attached to opposite sides of the channel layers 108′B, and the gate structure 211B (e.g. bottom gate structure) wrapping around the channel layers 108′B. Similarly, the transistor TsT includes the channel layers 108′T (e.g. top channel layers), the source/drain structures 150T attached to opposite sides of the channel layers 108′T, and the gate structure 211T (e.g. top gate structure) wrapping around the channel layers 108′T in accordance with some embodiments. In some embodiments, the threshold voltage of the transistor TsB is different from the threshold voltage of the transistor TsT.

As described previously, the isolation layer 149 is sandwiched between the topmost channel layer of the channel layers 108′B and the topmost channel layer of the channel layers 108′T to separate the channel structures in accordance with some embodiments. In addition, the isolation structures 212 are sandwiched between gate structures 211B and 211T to separate the gate structures in accordance with some embodiments. In addition, the doped regions 194 and 204 are formed at the upper portions of the gate spacers 140 and are separated by each other by un-doped regions of the gate spacers 140, as shown in FIGS. 1P-3, 1P-4, and 1P-5 in accordance with some embodiments. In some embodiments, each of the doped region 194 is wider than each of the doped region 204 in Y direction.

FIGS. 2A to 2C illustrate cross-sectional views of intermediate stages of manufacturing a semiconductor structure 100a in accordance with some embodiments. The semiconductor structure 100a may be similar to the semiconductor structure 100 described previously, except doped regions formed in the dummy material 180 are different from those in the semiconductor structure 100 in accordance with some embodiments. Some processes and materials for forming the semiconductor structure 100a may be similar to, or the same as, those for forming the semiconductor structure 100 described previously and are not repeated herein.

More specifically, the processes shown in FIGS. 1A to 1G are performed to form the dummy material 180 around the channel layers 108′-1 to 108′-4, and dope regions 202′ are formed in accordance with some embodiments. After the doped regions 202′ are formed, the processes shown in FIGS. 1J and 1K are performed to form the doped region 202, as shown in FIG. 2A in accordance with some embodiments. That is, instead of forming the doped region 192 in the space Sp2 which has a greatest width among other spaces, the doped regions 202′ are formed in the space Sp1 in accordance with some embodiments. The formation of the doped regions 202′ are configured to speed up the etching rate of the dummy material 180 during subsequent etching process (e.g. the second etching process 282).

The doped regions 202′ may be formed by forming a mask structure covering the spaces Sp2 and Sp3 and performing an implantation process to form the doped regions 202′ at the dummy material 180 exposed by the mask structure. In some embodiments, the doped region 202′ has a thickness (i.e. in the Z direction) in a range from about 0.5 nm to about 10 nm. In some embodiments, the doped regions 202 and 202′ include the same kind of dopants, but the dopant concentration are different. In some embodiments, the dopant concentration in the doped region 202 is greater than the dopant concentration in the doped regions 202′. In some embodiments, the doped regions 202′ include two types of dopants, such as Ge and C, N and Si, N and C, As and C, or P and C.

After the doped regions 202′ and 202 are formed, the second etching process 282 is performed to etch the dummy material 180, as shown in FIG. 2B in accordance with some embodiments. Similar to that described previously, since the doped regions 202 and 202′ are formed, the resulting heights H1′, H2′, and H3′ of the dummy material 180 at the spaces with different widths can be substantially level after the second etching process 282 is performed.

Afterwards, the processes shown in FIGS. 1M to 1P are performed to form the semiconductor structure 100a, as shown in FIGS. 2C, 2C-1 and 2C-2 in accordance with some embodiments. FIG. 2C-1 illustrates the top view of the semiconductor structure 100a in accordance with some embodiments. FIG. 2C illustrate the cross-sectional view of the semiconductor structure 100a shown along line Y_{MG}-Y_{MG}′ (i.e. in the Y direction) in FIG. 2C-1 in accordance with some embodiments. FIG. 2C-2 illustrates a cross-sectional view of the semiconductor structure 100a shown along line X_{Sp1} to X_{Sp1}′ in FIG. 2C-1 in accordance with some embodiments.

As shown in FIGS. 2C-1 and 2C-2, the gate spacer 140 include doped regions 204 and 204′ at the upper portions of the gate spacers 140 due to the formation of the doped regions 202 and 202′ in accordance with some embodiments. In addition, the doped regions 204 and 204′ are separated from each other by the un-doped regions of the gate spacer 140 in accordance with some embodiments. Other elements in the semiconductor structure 100a may be the same as those in the semiconductor structure 100 and therefore are not repeated herein.

FIGS. 3A to 3C illustrate cross-sectional views of intermediate stages of manufacturing a semiconductor structure 100b in accordance with some embodiments. The semiconductor structure 100b may be similar to the semiconductor structure 100 described previously, except doped regions formed in the dummy material 180 are different from those in the semiconductor structure 100 in accordance with some embodiments. Some processes and materials for forming the semiconductor structure 100b may be similar to, or the same as, those for forming the semiconductor structure 100 described previously and are not repeated herein.

More specifically, the processes shown in FIGS. 1A to 1I are performed to form the dummy material 180 around the channel layers 108′-1 to 108′-4, and dope regions 192′ are formed in accordance with some embodiments. That is, instead of forming the doped region 202 in the space Sp3, which has the smallest width among other spaces, the doped regions 192′ are formed in the space Sp1 in accordance with some embodiments. The formation of the doped regions 192′ are configured to slow down the etching rate of the dummy material 180 during subsequent etching process (e.g. the second etching process 282).

The doped regions 192′ may be formed by forming a mask structure covering the spaces Sp2 and Sp3 and performing an implantation process to form the doped regions 192′ at the dummy material 180 exposed by the mask structure. In some embodiments, the doped region 192′ has a thickness (i.e. in the Z direction) in a range from about 0.5 nm to about 10 nm. In some embodiments, the doped regions 192 and 192′ include the same kind of dopants, but the dopant concentration are different. In some embodiments, the dopant concentration in the doped region 192 is greater than the dopant concentration in the doped regions 192′. In some embodiments, the doped regions 192′ include a single type of dopants, such as C or Si. In some embodiments, the doped regions 192 include two types of dopants, such as Si and C, Ge and Si, or Ge and C. After the doped regions 192′ and 192 are formed, the second etching process 282 is performed to etch the dummy material 180, as shown in FIG. 3B in accordance with some embodiments. Similar to that described previously, since the doped regions 192 and 192′ are formed, the resulting heights H1′, H2′, and H3′ of the dummy material 180 at the spaces with different widths can be substantially level after the second etching process 282 is performed.

Afterwards, the processes shown in FIGS. 1M to 1P are performed to form the semiconductor structure 100b, as shown in FIGS. 3C, 3C-1 and 3C-2 in accordance with some embodiments. FIG. 3C-1 illustrates the top view of the semiconductor structure 100b in accordance with some embodiments. FIG. 3C illustrate the cross-sectional view of the semiconductor structure 100b shown along line Y_{MG}-Y_{MG}′ (i.e. in the Y direction) in FIG. 3C-1 in accordance with some embodiments. FIG. 3C-2 illustrates a cross-sectional view of the semiconductor structure 100b shown along line X_{Sp1} to X_{Sp1}′ in FIG. 3C-1 in accordance with some embodiments.

As shown in FIGS. 3C-1 and 3C-2, the gate spacer 140 include doped regions 194 and 194′ at the upper portions of the gate spacers 140 due to the formation of the doped regions 192 and 192′ in accordance with some embodiments. In addition, the doped regions 194 and 194′ are separated from each other by the un-doped regions of the gate spacer 140 in accordance with some embodiments. Other elements in the semiconductor structure 100b may be the same as those in the semiconductor structure 100 and therefore are not repeated herein.

FIGS. 4A to 4D illustrate cross-sectional views of intermediate stages of manufacturing a semiconductor structure 100c in accordance with some embodiments. The semiconductor structure 100c may be similar to the semiconductor structure 100 described previously, except only one semiconductor stack is formed over the substrate 102 in accordance with some embodiments. Some processes and materials for forming the semiconductor structure 100c may be similar to, or the same as, those for forming the semiconductor structure 100 described previously and are not repeated herein.

More specifically, the first semiconductor stack shown in FIG. 1A is replaced by a thicker substrate 102, and only one semiconductor stack, including the first semiconductor material layers 106 and the second semiconductor material layers 108 alternately stacked, is formed over the substrate 102 in accordance with some embodiments. The semiconductor stack, the middle layer 109, and the substrate 102 are patterned to form fin structures 104-1c, 104-2c, 104-3c, and 104-4c, as shown in FIG. 4A in accordance with some embodiments. Similar to the semiconductor structure 100, the semiconductor structure 100c also includes the bottom device region 10 and the top device region 20. However, the channel structure in the bottom device region 10 are fin structures 104Bc, instead of the channel layers 108′B described previously.

After the fin structures 104-1c to 104-4c are formed, the processes shown in FIGS. 1A to 1G are performed to form channel structures 108′-1c, 108′-2c, 108′-3c, and 108′-4c with the dummy material 180 formed in the spaces Sp1, Sp2, and Sp3, as shown in FIG. 4B in accordance with some embodiments. In some embodiments, each of the channel structures 108′-1c to 108′-4c includes the channel layers 108′T formed in the top device region 20 and the fin structure 104Bc formed in the bottom device region 10. In addition, the isolation layer 149 interposes the fin structure 104Bc and the channel layers 108′T in accordance with some embodiments.

Furthermore, the portions 170Bc of the interfacial layers 170 are formed on sidewalls the fin structures 104Bc, and the portions 172Bc of the gate dielectric layer 172 are formed over the portions 170Bc of the interfacial layer 170 in accordance with some embodiments. As described previously, since the spaces Sp1, Sp2, and Sp3 have different widths, the dummy material 180 at different spaces have different heights after the first etching process 182 is performed.

After the first etching process 182 is performed, the processes shown in FIGS. 1H to 1L, 2A to 2B, or 3A to 3B are performed, so that the dummy material 180 can have substantially the same height at the spaces Sp1, Sp2, and Sp3, as shown in FIG. 4C in accordance with some embodiments. Next, the processes shown in FIGS. 1M to 1P are performed to form the semiconductor structure 100c, as shown in FIGS. 4D, 4D-1, and 4D-2 in accordance with some embodiments. More specifically, FIGS. 4D, 4D-1, and 4D-2 illustrate cross-sectional views of the semiconductor structure 100c along the Y direction at the channel region, the Y direction at the source/drain region, and the X direction at the channel structure 108′-1c, respectively, in accordance with some embodiments. In addition, FIG. 4D-3, 4D-3′, and 4D-3″ illustrate the top view of the semiconductor structure 100c when formed by the processes shown in FIGS. 1H to 1L, 2A to 2B, and 3A to 3B, respectively, in accordance with some embodiments.

In some embodiments, the semiconductor structure 100c includes bottom transistors TsBc in the bottom device region 10 and the transistors TsT in the top device region 20. In addition, the transistors TsT vertically overlaps the transistors TsBc in accordance with some embodiments. In some embodiments, each transistor TsBc includes the fin structure 104Bc, the source/drain structures 150Bc attached to opposite sides of the fin structure 104Bc, and the gate structure 211Bc around the sidewalls of the channel structure 108Td. The processes and materials for forming the source/drain structures 150b and the gate structures 211Bc may be the same as those for forming the source/drain structures 150 and the gate structures 211B described previously and are not repeated herein.

FIGS. 5A to 5D illustrate cross-sectional views of intermediate stages of manufacturing a semiconductor structure 100d in accordance with some embodiments. The semiconductor structure 100d may be similar to the semiconductor structure 100 described previously, except the second semiconductor stack is replaced by a single semiconductor material layer 108Td in accordance with some embodiments. Some processes and materials for forming the semiconductor structure 100d may be similar to, or the same as, those for forming the semiconductor structure 100 described previously and are not repeated herein.

More specifically, a single second semiconductor material layer 108Td is formed over the middle layer 109, and the second semiconductor material layer 108Td, the first semiconductor stack formed below it, and the substrate 102 are patterned to form fin structures 104-1d, 104-2d, 104-3d, and 104-4d, as shown in FIG. 5A in accordance with some embodiments. Similar to the semiconductor structure 100, the semiconductor structure 100d also includes the bottom device region 10 and the top device region 20. However, the channel structure in the top device region 20 are a single channel structure 108Td, instead of the channel layers 108′T described previously.

After the fin structures 104-1d to 104-4d are formed, the processes shown in FIGS. 1A to 1G are performed to form channel structures 108′-1d, 108′-2d, 108′-3d, and 108′-4d with the dummy material 180 formed in the spaces Sp1, Sp2, and Sp3, as shown in FIG. 5B in accordance with some embodiments. In some embodiments, each of the channel structures 108′-1d to 108′-4d includes the channel layer 108Td formed in the top device region 20 and the channel layers 108′B formed in the bottom device region 10. In addition, the isolation layer 149 interposes the channel structure 108Bd and the channel layers 108′B in accordance with some embodiments. Furthermore, the portions 170Td of the interfacial layers 170 are formed on sidewalls the channel structures 108Td, and the portions 172Td of the gate dielectric layer 172 are formed over the portions 170Td of the interfacial layer 170 in accordance with some embodiments. As described previously, since the spaces Sp1, Sp2, and Sp3 have different widths, the dummy material 180 at different spaces have different heights after the first etching process 182 is performed.

After the first etching process 182 is performed, the processes shown in FIGS. 1H to 1L, 2A to 2B, or 3A to 3B are performed, so that the dummy material 180 can have substantially the same height at the spaces Sp1, Sp2, and Sp3 after the second etching process 282 is performed, as shown in FIG. 5C in accordance with some embodiments. Next, the processes shown in FIGS. 1M to 1P are performed to form the semiconductor structure 100d, as shown in FIGS. 5D, 5D-1, and 5D-2 in accordance with some embodiments. More specifically, FIGS. 5D, 5D-1, and 5D-2 illustrate cross-sectional views of the semiconductor structure 100d along the Y direction at the channel region, the Y direction at the source/drain region, and at the X direction at the channel structure 108′-1c, respectively, in accordance with some embodiments. In addition, FIG. 5D-3, 5D-3′, and 5D-3″ illustrate the top view of the semiconductor structure 100d when formed by the processes shown in FIGS. 1H to IL, 2A to 2B, and 3A to 3B, respectively, in accordance with some embodiments.

In some embodiments, the semiconductor structure 100d includes bottom transistors TsB in the bottom device region 10 and the transistors TsTd in the top device region 20. In addition, the transistors TsTd vertically overlaps the transistors TsB in accordance with some embodiments. In some embodiments, each of the transistors TsTd includes the channel structure 108Td, the source/drain structures 150Bd attached to opposite sides of the channel structure 108Td, and the gate structure 211Td around the sidewalls of the channel structure 108Td. The processes and materials for forming the channel structure 108Bt, the source/drain structures 150b and the gate structures 211Bc may be the same as those for forming the second semiconductor material layer 108, the source/drain structures 150 and the gate structures 211B described previously and are not repeated herein.

Generally, CFET structures include a top device region and a bottom device region, and a dummy material may be formed as a protection layer for the structure in the bottom device region during the formation of the top device region and the bottom device region. However, when a numbers of CFET structures are formed, the control of an etching back process of the dummy material may be difficult when the widths between the neighboring channel structures are different. More specifically, the dummy material formed in a wider space may have a greater etching rate, while the dummy material formed in a narrower space may have a less etching rate. Therefore, the height of the dummy material formed in the wider space may be lower than the height of the dummy material formed in the narrower space. However, if the heights of the dummy material at different regions are not uniform, the structures in the bottom device region adjacent to the wider space may not be completely protected (i.e. covered) by the dummy material, while the structures in the top device region adjacent to the narrower space may not be completely exposed (i.e. partially covered) by the dummy material.

Accordingly, additional implantation processes (e.g. the implantation processes 190 and 200) are performed to formed doped regions (e.g. the doped regions 192, 202, 192′ and 202′) in the dummy material (e.g. the dummy material 180). The doped regions formed in the dummy material may help to slow down or speed up the etching rates of the dummy material during the etching process (e.g. the second etching process 282). Therefore, the dummy material at different spaces (e.g. the spaces Sp1, Sp2, and Sp3) can have substantially the same height after the etching process, and the structure in the bottom device region (e.g. the bottom device region 10) can be well protected while manufacturing the structure in the top device region (e.g. the top device region 20).

It should be appreciated that the elements shown in the semiconductor structures 100, 100a, 100b, 100c, and 100d may be combined and/or exchanged. For example, the semiconductor structure may include more than two kinds of doped regions, or more than one implantation process may be performed on the same regions in the dummy material 180.

In addition, it should be noted that same elements in FIGS. 1A to 5D-3″ may be designated by the same numerals and may include materials that are the same or similar and may be formed by processes that are the same or similar; therefore such redundant details are omitted in the interests of brevity. In addition, although FIGS. 1A to 5D-3″ are described in relation to the method, it will be appreciated that the structures disclosed in FIGS. 1A to 5D-3″ are not limited to the method but may stand alone as structures independent of the method. Similarly, the methods shown in FIGS. 1A to 5D-3″ are not limited to the disclosed structures but may stand alone independent of the structures. Furthermore, the channel structures described above may include nanostructures, nanowires, nanosheets, fin structures, or other applicable channel structures in accordance with some embodiments.

Also, while the disclosed methods are illustrated and described below as a series of acts or events, it should be appreciated that the illustrated ordering of such acts or events may be altered in some other embodiments. For example, some acts may occur in a different order and/or concurrently with other acts or events apart from those illustrated and/or described above. In addition, not all illustrated acts may be required to implement one or more aspects or embodiments of the description above. Furthermore, one or more of the acts depicted above may be carried out as one or more separate acts and/or phases.

Furthermore, the terms “approximately,” “substantially,” “substantial” and “about” used above account for small variations and may be varied in different technologies and be within the deviation range understood by the skilled in the art. For example, when used in conjunction with an event or circumstance, the terms can refer to instances in which the event or circumstance occurs precisely as well as instances in which the event or circumstance occurs in a close approximation.

Embodiments for forming semiconductor structures may be provided. The semiconductor structure may include forming first channel structures, second channel structures, and third channel structures over a substrate, and a first space between the first channel structures and the second channel structures is different from a second space between the second channel structure and the thirds channel structures. A dummy material may be formed in the first space and the second space, and a first etching process may be performed. The etching rate of the dummy material in the first space may be different from the etching rate of the dummy material in the second space due to the difference of the widths of the first space and the second space, such that the dummy material in the first space and the dummy material in the second space may have different heights. An implantation process may be performed to form a doped region in the dummy material in the first space but not in the second space. The doped region may help to speed up or slow down the etching rate in subsequent etching process. After the doped region is formed, a second etching process may be performed, and the dummy material in the first space and the dummy material in the second space may have substantially the same height due to the formation of the doped region. Accordingly, the uniformity of the dummy material in the manufacturing processes for forming the semiconductor structure may be improved, and the yield of the resulting semiconductor structure may therefore be improved.

In some embodiments, a method for manufacturing a semiconductor structure is provided. The method for manufacturing the semiconductor structure includes forming first channel structures, second channel structures, and third channel structures, and the first channel structures, the second channel structures, and the third channel structures in a top device region are vertically separated from the first channel structures, the second channel structures, and the third channel structures in a bottom device region. The method for manufacturing the semiconductor structure also includes forming gate dielectric layers surrounding the first channel structures, the second channel structures, and the third channel structures and forming dipole layers over the gate dielectric layers. The method for manufacturing the semiconductor structure also includes forming a dummy material in a first space between the first channel structures and the second channel structures and in a second space between the second channel structures and the third channel structures and removing first portions of the dummy material in the first space and the second space by performing a first etching process. The method for manufacturing the semiconductor structure also includes implanting first dopants in the dummy material in the first space and removing second portions of the dummy material in the first space and the second space by performing a second etching process. The method for manufacturing the semiconductor structure also includes removing the dipole layers in the top device region and completely removing the dummy material.

In some embodiments, a method for manufacturing a semiconductor structure is provided. The method for manufacturing the semiconductor structure includes forming a first semiconductor stack over a substrate and a second semiconductor stack over the first semiconductor stack, and each of the first semiconductor stack and the second semiconductor stack includes first semiconductor material layers and second semiconductor material layers alternately stacked in a first direction. The method for manufacturing the semiconductor structure also includes patterning the first semiconductor stack and the second semiconductor stack to form a first fin structure, a second fin structure, and a third fin structure longitudinally oriented in a second direction and separated from each other in a third direction different from the first direction and the second direction and removing the first semiconductor material layers in the first fin structure, the second fin structure, and the third fin structure. The method for manufacturing the semiconductor structure also includes forming first dipole layers wrapping around the second semiconductor material layers of the first fin structure, the second fin structure, and third fin structure and filling a first space between the second semiconductor material layers of the first fin structure and the second fin structure and a second space between the second semiconductor material layers of the second fin structure and the third fin structure with a dummy material. The method for manufacturing the semiconductor structure also includes etching the dummy material so that the dummy material has a first height in the first space and a second height in the second space in the first direction and forming a first doped region in the dummy material in the first space. The method for manufacturing the semiconductor structure also includes etching the first doped region of the dummy material in the first space and the dummy material in the second space so that the dummy material has a third height in the first space and a fourth height in the second space in the first direction. In addition, a difference between the first height and the third height is different from a difference between the second height and the fourth height. The method for manufacturing the semiconductor structure also includes removing the first dipole layers not covered by the dummy material and completely removing the dummy material.

In some embodiments, a semiconductor structure is provided. The semiconductor structure includes a first complementary field-effect transistor (CFET) structure, a second CFET structure, and a third CFET structure formed over a substrate. In addition, each of the first CFET structure, the second CFET structure, and the third CFET structure includes a top transistor and a bottom transistor. The top transistor includes a bottom channel structure and a bottom gate structure surrounding the bottom channel structure and extending along a first direction. The bottom transistor vertically formed over the top transistor and includes a top channel structure and a top gate structure surrounding the top channel structure and extending along the first direction. The semiconductor structure also includes an isolation layer vertically sandwiched between the bottom channel structure and the top channel structure and a gate spacer covering sidewalls of the top gate structures of the first CFET structure, the second CFET structure, and the third CFET structure. In addition, the gate spacer includes a first doped region and a second doped region, and the first doped region is wider than the second doped region in the first direction.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor structure, comprising:
forming first channel structures, second channel structures, and third channel structures, wherein the first channel structures, the second channel structures, and the third channel structures in a top device region are vertically separated from the first channel structures, the second channel structures, and the third channel structures in a bottom device region;
forming gate dielectric layers surrounding the first channel structures, the second channel structures, and the third channel structures;
forming dipole layers over the gate dielectric layers;
forming a dummy material in a first space between the first channel structures and the second channel structures and in a second space between the second channel structures and the third channel structures;
removing first portions of the dummy material in the first space and the second space by performing a first etching process;
implanting first dopants in the dummy material in the first space;
removing second portions of the dummy material in the first space and the second space by performing a second etching process;
removing the dipole layers in the top device region; and
completely removing the dummy material.

2. The method for manufacturing the semiconductor structure as claimed in claim 1, wherein a first width of the first space is different from a second width of the second space.

3. The method for manufacturing the semiconductor structure as claimed in claim 1, wherein an etching rate of the dummy material in the first space is different from an etching rate of the dummy material in the second space during the second etching process.

4. The method for manufacturing the semiconductor structure as claimed in claim 1, further comprising:
implanting second dopants in the dummy material in the second space before performing the second etching process, wherein the first dopants are different from the second dopants.

5. The method for manufacturing the semiconductor structure as claimed in claim 1, wherein the first dopants comprise Si, C, P, Ge, As, N, or a combination thereof.

6. The method for manufacturing the semiconductor structure as claimed in claim 1, wherein a top surface of the dummy material after performing the second etching process is higher than the first channel structures, the second channel structures, and the third channel structures in the bottom device region.

7. The method for manufacturing the semiconductor structure as claimed in claim 1, further comprising:
annealing the dipole layers in the bottom device region to form modified gate dielectric layers in the bottom device region after completely removing the dummy material; and
removing the dipole layers.

8. The method for manufacturing the semiconductor structure as claimed in claim 7, further comprising:
forming first gate filling layers (210B) in the bottom device region (10) and second gate filling layers (210T) in the top device region (20), wherein the first gate filling layers vertically overlap the second gate filling layers.

9. A method for manufacturing a semiconductor structure, comprising:
forming a first semiconductor stack over a substrate and a second semiconductor stack over the first semiconductor stack, wherein each of the first semiconductor stack and the second semiconductor stack comprises first semiconductor material layers and second semiconductor material layers alternately stacked in a first direction;
patterning the first semiconductor stack and the second semiconductor stack to form a first fin structure, a second fin structure, and a third fin structure longitudinally oriented in a second direction and separated from each other in a third direction different from the first direction and the second direction;
removing the first semiconductor material layers in the first fin structure, the second fin structure, and the third fin structure;
forming first dipole layers wrapping around the second semiconductor material layers of the first fin structure, the second fin structure, and third fin structure;
filling a first space between the second semiconductor material layers of the first fin structure and the second fin structure and a second space between the second semiconductor material layers of the second fin structure and the third fin structure with a dummy material;
etching the dummy material so that the dummy material has a first height in the first space and a second height in the second space in the first direction;
forming a first doped region in the dummy material in the first space;
etching the first doped region of the dummy material in the first space and the dummy material in the second space so that the dummy material has a third height in the first space and a fourth height in the second space in the first direction, wherein a difference between the first height and the third height is different from a difference between the second height and the fourth height;
removing the first dipole layers not covered by the dummy material; and
completely removing the dummy material.

10. The method for manufacturing the semiconductor structure as claimed in claim 9, wherein a width of the first space in the third direction is greater than a width of the second space in the third direction, and the difference between the first height and the third height is smaller than the difference between the second height and the fourth height, and the first doped region comprises C, Si, or a combination thereof.

11. The method for manufacturing the semiconductor structure as claimed in claim 9, wherein a width of the first space in the third direction is smaller than a width of the second space in the third direction, and the difference between the first height and the third height is greater than the difference between the second height and the fourth height, and the first doped region comprises P, As, N, Si, C, or a combination thereof.

12. The method for manufacturing the semiconductor structure as claimed in claim 9, further comprising:
forming a second doped region in the dummy material in the second space,
wherein the first doped region and the second doped region comprise different dopants.

13. The method for manufacturing the semiconductor structure as claimed in claim 12, wherein the first doped region is partially removed and the second doped region is completely removed before removing the first dipole layers not covered by the dummy material.

14. The method for manufacturing the semiconductor structure as claimed in claim 9, further comprising:
forming a second doped region in the dummy material in the second space,
wherein a dopant concentration of the first doped region is different from a dopant concentration in the second doped region.

15. The method for manufacturing the semiconductor structure as claimed in claim 9, further comprising:
forming gate dielectric layers wrapping around the second semiconductor material layers before forming the first dipole layers;
driving metal elements in the first dipole layers into the gate dielectric layers; and
removing the first dipole layers.

16. A semiconductor structure, comprising:
a first complementary field-effect transistor (CFET) structure, a second CFET structure, and a third CFET structure formed over a substrate, wherein each of the first CFET structure, the second CFET structure, and the third CFET structure comprises:
a bottom transistor, comprising:
a bottom channel structure; and
a bottom gate structure surrounding the bottom channel structure and extending along a first direction;
a top transistor vertically formed over the bottom transistor, comprising:
a top channel structure; and
a top gate structure surrounding the top channel structure and extending along the first direction; and
an isolation layer vertically sandwiched between the bottom channel structure and the top channel structure; and
a gate spacer covering sidewalls of the top gate structures of the first CFET structure, the second CFET structure, and the third CFET structure,
wherein the gate spacer comprises a first doped region and a second doped region, and the first doped region is wider than the second doped region in the first direction.

17. The semiconductor structure as claimed in claim 16, wherein the first doped region comprises C, Si, or a combination thereof, and the second doped region comprises P, As, N, Si, C, or a combination thereof.

18. The semiconductor structure as claimed in claim 16, wherein the first doped region is separated from the second doped region by an un-doped region.

19. The semiconductor structure as claimed in claim 16, wherein the first doped region is located between the top channel structure in the first CFET structure and the top channel structure of the second CFET structure, and the second doped region is located between the top channel structure in the second CFET structure and the top channel structure in the third CFET structure.

20. The semiconductor structure as claimed in claim 16, wherein the bottom channel structures in the first CFET structure, the second CFET structure, and the third CFET structure are fin structures protruding from the substrate, and each of the top channel structures in the first CFET structure, the second CFET structure, and the third CFET structure comprises at least two channel layers vertically separated from each other.
